(19) United States
(12) Patent Application Publication
(10) Pub. No.: US 2026/0129976 A1
(43) Pub. Date: May 7, 2026

(54) ELECTROSTATIC DISCHARGE PROTECTION DEVICE

(71) Applicant: AMAZING MICROELECTRONIC CORP., New Taipei City (TW)

(72) Inventors: Chih-Wei CHEN, Zhubei City (TW); Kuan-Yu LIN, New Taipei City (TW); Kun-Hsien LIN, Hsinchu City (TW)

(73) Assignee: AMAZING MICROELECTRONIC CORP., New Taipei City (TW)

(21) Appl. No.: 18/939,366

(22) Filed: Nov. 6, 2024

(51) Int. Cl. H01L 27/02; H02H 9/04

(52) U.S. Cl. CPC H10D 89/611; H02H 9/046

(57) ABSTRACT

An electrostatic discharge protection device includes a diode, a voltage clamping component, an electronic component, a first pin, and a second pin. The diode includes a first doped area of a first conductivity type and a second doped area of a second conductivity type opposite to the first conductivity type. The voltage clamping component is electrically connected to the first doped area. The electronic component includes a first region of the first conductivity type, a second region of the second conductivity type, a third region of the first conductivity type, and a fourth region of the second conductivity type. The first region is electrically connected to the second doped area. The second region is electrically connected to the first doped area and the voltage clamping component. The fourth region is electrically connected to the voltage clamping component.

### BACKGROUND OF THE INVENTION

### FIELD OF THE INVENTION

The present invention relates to a protection device, particularly to an electrostatic discharge protection device.

### DESCRIPTION OF THE RELATED ART

As the IC device sizes have been shrunk to nanometer scale, the consumer electronics, like the laptop and mobile devices, have been designed to be much smaller than ever. Without suitable protection devices, the functions of these electronics could be reset or even damaged under electrostatic discharge (ESD) events. Currently, all consumer electronics are expected to pass the ESD test requirement of IEC 61000-4-2 standard. Transient voltage suppressor (TVS) is generally designed to bypass the ESD energy, so that the electronic systems can be prevented from ESD damages.

The working principle of transient voltage suppression (TVS) device is shown in FIG. 1. In FIG. 1, a TVS device 10 is connected in parallel with a protected circuit 12 on the printed circuit board (PCB). The transient voltage suppression device 10 would be triggered immediately when the ESD event occurs. In that way, the transient voltage suppression device 10 can provide a superiorly low resistance path for discharging the transient ESD current, so that the energy of the ESD transient current can be bypassed by the transient voltage suppression device 10. The US Patent No. 8217421 B2 disclosed a uni-directional vertical PNP electrostatic discharge device triggered by a trigger node. The parasitic capacitance of the vertical PNP electrostatic discharge device depends on a P-type heavily-doped area, an N-type well, a P-type heavily-doped substrate, and a P-type well. Thus, the vertical PNP electrostatic discharge device has a large parasitic capacitance. The US Patent Publication No.2018/0047717 A1 disclosed a vertical NPN bipolar junction transistor connected to a diode in parallel. Since the diode is a single-junction capacitance component, the overall capacitance of the ESD protection device is large. The US Patent No. 10930637 B2 disclosed a vertical bipolar junction transistor connected to a PNPN diode in parallel. The PNPN diode has a reverse-biased junction to cause a higher trigger voltage when the PNPN diode is turned on.

To overcome the abovementioned problems, the present invention provides an electrostatic discharge protection device, so as to solve the afore-mentioned problems of the prior art.

### SUMMARY OF THE INVENTION

The present invention provides an electrostatic discharge protection device, which has low capacitance and low trigger voltage.

In an embodiment of the present invention, an electrostatic discharge protection device includes at least one voltage clamping device. The voltage clamping device includes a diode, a voltage clamping component, an electronic component, a first pin, and a second pin. The diode includes a first doped area of a first conductivity type and a second doped area of a second conductivity type opposite to the first conductivity type. The voltage clamping component has a first terminal and a second terminal. The first terminal of the voltage clamping component is electrically connected to the first doped area. The electronic component includes a first region of the first conductivity type, a second region of the second conductivity type, a third region of the first conductivity type, and a fourth region of the second conductivity type. The first region, the second region, the third region, and the fourth region are adjacent to each other. The second region is arranged between the first region and the third region. The third region is arranged between the second region and the fourth region. The first region is electrically connected to the second doped area. The second region is electrically connected to the first doped area and the first terminal of the voltage clamping component. The fourth region is electrically connected to the second terminal of the voltage clamping component. The first pin is electrically connected to the second doped area and the first region. The second pin is electrically connected to the second terminal of the voltage clamping component and the fourth region.

In an embodiment of the present invention, the first conductivity type is an N type and the second conductivity type is a P type.

In an embodiment of the present invention, when the first pin receives a positive pulse voltage and the second pin receives a reference voltage lower than the positive pulse voltage, an electrostatic discharge current flows from the first pin to the second pin through the diode and the voltage clamping component. And when the first pin receives a negative pulse voltage and the second pin receives a reference voltage higher than the negative pulse voltage, a first electrostatic discharge current flows from the second pin to the first pin through the voltage clamping component, the second region, and the first region and a second electrostatic discharge current flows from the second pin to the first pin through the electronic component.

In an embodiment of the present invention, the first conductivity type is a P type and the second conductivity type is an N type.

In an embodiment of the present invention, when the second pin receives a reference voltage and the first pin receives a negative pulse voltage lower than the reference voltage, an electrostatic discharge current flows from the second pin to the first pin through the voltage clamping component and the diode. And the first pin receives a positive pulse voltage and the second pin receives a reference voltage lower than the positive pulse voltage, a first electrostatic discharge current flows from the first pin to second the pin through the first region, the second region, and the voltage clamping component and a second electrostatic discharge current flows from the first pin to the second pin through the electronic component.

In an embodiment of the present invention, the voltage clamping component is a Zener diode, an NPN bipolar junction transistor whose base is electrically floating, an NPN bipolar junction transistor whose emitter is coupled to its base, a PNP bipolar junction transistor whose base is electrically floating, or a PNP bipolar junction transistor whose emitter is coupled to its base.

In an embodiment of the present invention, the at least one voltage clamping device comprises two voltage clamping devices. The second pin of one of the two voltage clamping devices is electrically connected to the second pin of another of the two voltage clamping devices.

In an embodiment of the present invention, the at least one voltage clamping device comprises two voltage clamping devices. The first pin of one of the two voltage clamping devices is electrically connected to the first pin of another of the two voltage clamping devices.

In an embodiment of the present invention, the fourth region is implemented with a heavily-doped region. The third region is implemented with a first epitaxial region and a second epitaxial region. The second region is implemented with a first doped well. The first region is implemented with a first heavily-doped area. The first epitaxial region and the second epitaxial region are sequentially formed on the heavily-doped region. The first doped well is formed in the second epitaxial region. The first heavily-doped area and a second heavily-doped area of the second conductivity type are formed in the first doped well. A third heavily-doped area of the first conductivity type and a fourth heavily-doped area of the second conductivity type are formed in the second epitaxial region. The second heavily-doped area is electrically connected to the third heavily-doped area. The first heavily-doped area is electrically connected to the fourth heavily-doped area. The first doped area is implemented with the second epitaxial region and the third heavily-doped area. The second doped area is implemented with the fourth heavily-doped area. The voltage clamping component is implemented with the heavily-doped region and the first epitaxial region.

In an embodiment of the present invention, the doping concentration of the first epitaxial region is greater than or equal to that of the second epitaxial region.

In an embodiment of the present invention, the electrostatic discharge protection device further includes two isolation structures formed in the heavily-doped region, the first epitaxial region, and the second epitaxial region. One of the isolation structures surrounds the first doped well, the first heavily-doped area, and the second heavily-doped area and another of the isolation structures surrounds the third heavily-doped area and the fourth heavily-doped area.

In an embodiment of the present invention, the electrostatic discharge protection device further includes a buried region of the first conductivity type formed in the first epitaxial region and formed between the fourth heavily-doped area and the heavily-doped region. The doping concentration of the buried region is greater than that of the first epitaxial region.

In an embodiment of the present invention, the fourth region is implemented with a heavily-doped region. The third region is implemented with a first epitaxial region and a second epitaxial region. The second region is implemented with a first doped well. The first region is implemented with a first heavily-doped area. The first epitaxial region and the second epitaxial region are sequentially formed on the heavily-doped region. The first doped well and a second doped well of the first conductivity type are formed in the second epitaxial region. The first heavily-doped area and a second heavily-doped area of the second conductivity type are formed in the first doped well. A third heavily-doped area of the first conductivity type and a fourth heavily-doped area of the second conductivity type are formed in the second doped well. The second heavily-doped area is electrically connected to the third heavily-doped area. The first heavily-doped area is electrically connected to the fourth heavily-doped area. The first doped area is implemented with the second doped well and the third heavily-doped area. The second doped area is implemented with the fourth heavily-doped area. The voltage clamping component is implemented with the heavily-doped region and the first epitaxial region.

In an embodiment of the present invention, the fourth region is implemented with a heavily-doped region. The third region is implemented with a first epitaxial region. The second region is implemented with a second epitaxial region. The first region is implemented with a first heavily-doped area. The first epitaxial region and the second epitaxial region are sequentially formed on the heavily-doped region. The first heavily-doped area and a second heavily-doped area of the second conductivity type are formed in the second epitaxial region. A third heavily-doped area of the first conductivity type and a fourth heavily-doped area of the second conductivity type are formed in a doped well of the first conductivity type. The doped well is formed in the second epitaxial region. The second heavily-doped area is electrically connected to the third heavily-doped area. The first heavily-doped area is electrically connected to the fourth heavily-doped area. The first doped area is implemented with the doped well and the third heavily-doped area. The second doped area is implemented with the fourth heavily-doped area. The voltage clamping component is implemented with the heavily-doped region and the first epitaxial region.

To sum up, the electrostatic discharge protection device employs the electronic component as a multi-junction component with low capacitance and uses the voltage clamping component to help trigger on the electronic component, such that the electrostatic discharge protection device has low trigger voltage.

Below, the embodiments are described in detail in cooperation with the drawings to make easily understood the technical contents, characteristics and accomplishments of the present invention.

### BRIEF DESCRIPTION OF THE DRAWINGS

FIG. 1 is a schematic diagram illustrating a conventional transient voltage suppression (TVS) device;

FIG. 2 is a schematic diagram illustrating an electrostatic discharge protection device according to a first embodiment of the present invention;

FIG. 3 is a cross-sectional view of an electrostatic discharge protection device according to a second embodiment of the present invention;

FIG. 4 is a schematic diagram illustrating an equivalent circuit of the electrostatic discharge protection device of FIG. 3;

FIG. 5 is a schematic diagram illustrating a current-voltage curve of the electrostatic discharge protection device of FIG. 3;

FIG. 6 is a cross-sectional view of an electrostatic discharge protection device according to a third embodiment of the present invention;

FIG. 7 is a cross-sectional view of an electrostatic discharge protection device according to a fourth embodiment of the present invention;

FIG. 8 is a cross-sectional view of an electrostatic discharge protection device according to a fifth embodiment of the present invention;

FIG. 9 is a schematic diagram illustrating an equivalent circuit of the electrostatic discharge protection device of FIG. 8;

FIG. 10 is a schematic diagram illustrating a current-voltage curve of the electrostatic discharge protection device of FIG. 8;

FIG. 11 is a cross-sectional view of an electrostatic discharge protection device according to a sixth embodiment of the present invention;

FIG. 12 is a schematic diagram illustrating an equivalent circuit of the electrostatic discharge protection device of FIG. 11;

FIG. 13 is a cross-sectional view of an electrostatic discharge protection device according to a seventh embodiment of the present invention;

FIG. 14 is a cross-sectional view of an electrostatic discharge protection device according to an eighth embodiment of the present invention;

FIG. 15 is a cross-sectional view of an electrostatic discharge protection device according to a ninth embodiment of the present invention;

FIG. 16 is a cross-sectional view of an electrostatic discharge protection device according to a tenth embodiment of the present invention;

FIG. 17 is a cross-sectional view of an electrostatic discharge protection device according to an eleventh embodiment of the present invention;

FIG. 18 is a schematic diagram illustrating an electrostatic discharge protection device according to a twelfth embodiment of the present invention;

FIG. 19 is a cross-sectional view of an electrostatic discharge protection device according to a thirteenth embodiment of the present invention;

FIG. 20 is a schematic diagram illustrating an equivalent circuit of the electrostatic discharge protection device of FIG. 19;

FIG. 21 is a schematic diagram illustrating a current-voltage curve of the electrostatic discharge protection device of FIG. 19;

FIG. 22 is a cross-sectional view of an electrostatic discharge protection device according to a fourteenth embodiment of the present invention;

FIG. 23 is a cross-sectional view of an electrostatic discharge protection device according to a fifteenth embodiment of the present invention;

FIG. 24 is a cross-sectional view of an electrostatic discharge protection device according to a sixteenth embodiment of the present invention;

FIG. 25 is a cross-sectional view of an electrostatic discharge protection device according to a seventeenth embodiment of the present invention;

FIG. 26 is a cross-sectional view of an electrostatic discharge protection device according to an eighteenth embodiment of the present invention;

FIG. 27 is a cross-sectional view of an electrostatic discharge protection device according to a nineteenth embodiment of the present invention;

FIG. 28 is a cross-sectional view of an electrostatic discharge protection device according to a twentieth embodiment of the present invention.

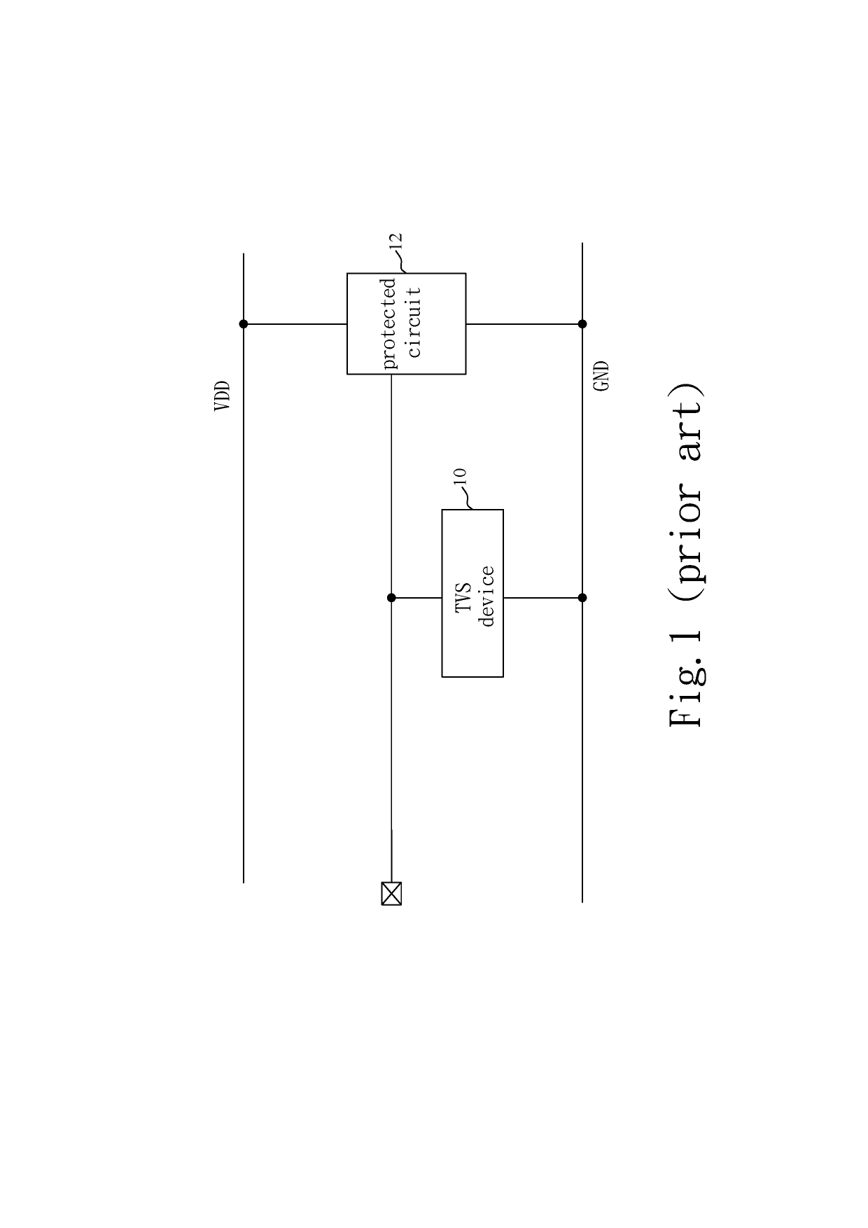

### DETAILED DESCRIPTION OF THE INVENTION

Reference will now be made in detail to embodiments illustrated in the accompanying drawings. Wherever possible, the same reference numbers are used in the drawings and the description to refer to the same or like parts. In the drawings, the shape and thickness may be exaggerated for clarity and convenience. This description will be directed in particular to elements forming part of, or cooperating more directly with, methods and apparatus in accordance with the present disclosure. It is to be understood that elements not specifically shown or described may take various forms well known to those skilled in the art. Many alternatives and modifications will be apparent to those skilled in the art, once informed by the present disclosure.

Unless otherwise specified, some conditional sentences or words, such as “can”, “could”, “might”, or “may”, usually attempt to express what the embodiment in the present invention has, but it can also be interpreted as a feature, element, or step that may not be needed. In other embodiments, these features, elements, or steps may not be required.

Reference throughout this specification to “one embodiment” or “an embodiment” means that a particular feature, structure, or characteristic described in connection with the embodiment is included in at least one embodiment. Thus, the appearances of the phrases "in one embodiment" or “in an embodiment” in various places throughout this specification are not necessarily all referring to the same embodiment.

Certain terms are used throughout the description and the claims to refer to particular components. One skilled in the art appreciates that a component may be referred to using different names. This disclosure does not intend to distinguish between components that differ in name but not in function. In the description and in the claims, the term “comprise” is used in an open-ended fashion, and thus should be interpreted to mean “include, but not limited to.” The phrases “be coupled to,” “couples to,” and “coupling to” are intended to encompass any indirect or direct connection. Accordingly, if this disclosure mentions that a first device is coupled with a second device, it means that the first device may be directly or indirectly connected to the second device through electrical connections, wireless communications, optical communications, or other signal connections with/without other intermediate devices or connection means.

The invention is particularly described with the following examples which are only for instance. Those skilled in the art will readily observe that numerous modifications and alterations of the device and method may be made while retaining the teachings of the invention. Accordingly, the following disclosure should be construed as limited only by the metes and bounds of the appended claims. In the whole patent application and the claims, except for clearly described content, the meaning of the articles “a” and “the” includes the meaning of “one or at least one” of the elements or components. Moreover, in the whole patent application and the claims, except that the plurality can be excluded obviously according to the context, the singular articles also contain the description for the plurality of elements or components. In the entire specification and claims, unless the contents clearly specify the meaning of some terms, the meaning of the article “wherein” includes the meaning of the articles “wherein” and “whereon”. The meanings of every term used in the present claims and specification refer to a usual meaning known to one skilled in the art unless the meaning is additionally annotated. Some terms used to describe the invention will be discussed to guide practitioners about the invention. The examples in the present specification do not limit the claimed scope of the invention.

Throughout the description and claims, it will be understood that when a component is referred to as being "positioned on," "positioned above," "connected to," "engaged with," or "coupled with" another component, it can be directly on, directly connected to, or directly engaged with the other component, or intervening component may be present. In contrast, when a component is referred to as being "directly on," "directly connected to," or "directly engaged with" another component, there are no intervening components present.

In the following description, an electrostatic discharge (ESD) protection will be provided, which employs an electronic component as a multi-junction component with low capacitance and uses a voltage clamping component to help trigger on the electronic component, such that the electrostatic discharge protection device has low trigger voltage.

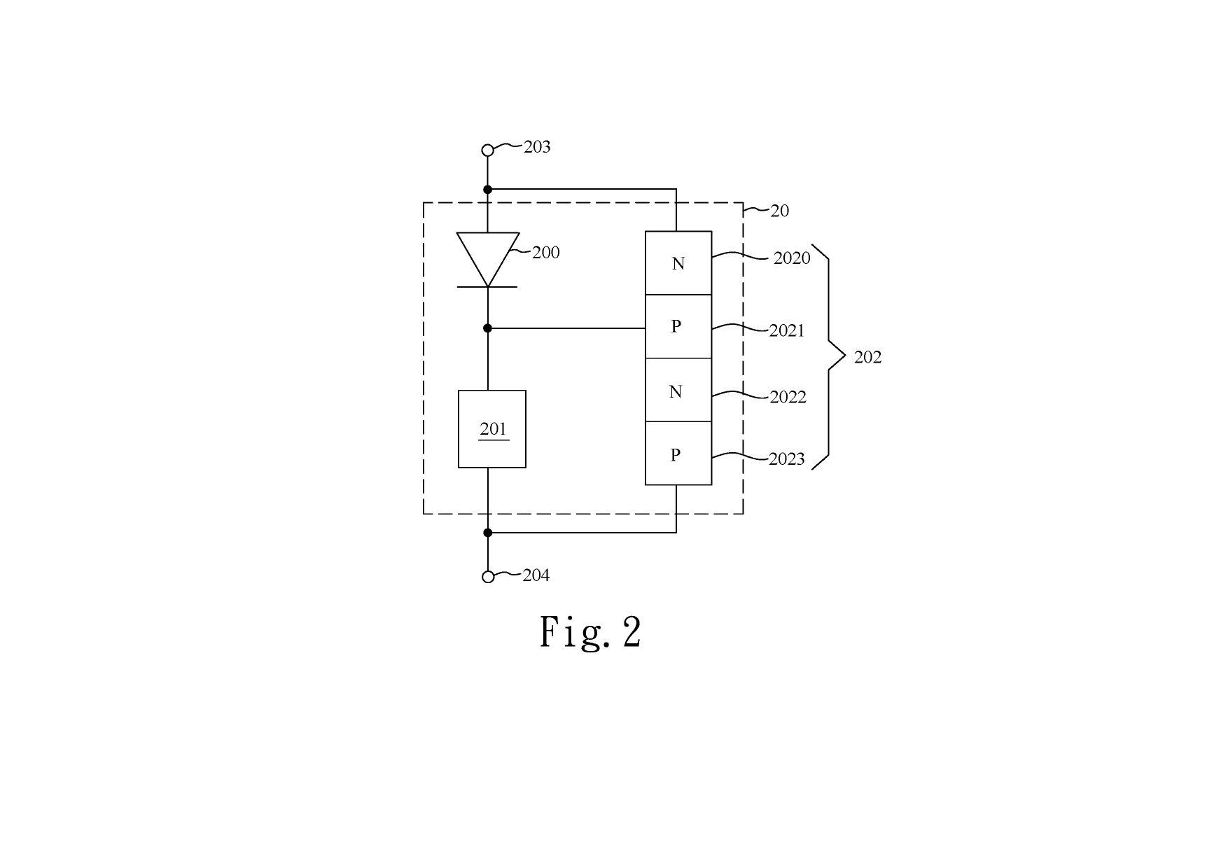

FIG. 2 is a schematic diagram illustrating an electrostatic discharge protection device according to a first embodiment of the present invention. Referring to FIG. 2, the first embodiment of an electrostatic discharge protection device 2 will be introduced as follows. The electrostatic discharge protection device 2 includes at least one voltage clamping device 20. For clarity and convenience, the first embodiment is exemplified by one voltage clamping device 20. The voltage clamping device 20 includes a diode 200, a voltage clamping component 201, an electronic component 202, a first pin 203, and a second pin 204. The diode 200 includes a first doped area of a first conductivity type and a second doped area of a second conductivity type opposite to the first conductivity type. The voltage clamping component 201 has a first terminal and a second terminal. The first terminal of the voltage clamping component 201 is electrically connected to the first doped area of the diode 200. The electronic component 202 includes a first region 2020 of the first conductivity type, a second region 2021 of the second conductivity type, a third region 2022 of the first conductivity type, and a fourth region 2023 of the second conductivity type. The first region 2020, the second region 2021, the third region 2022, and the fourth region 2023 are adjacent to each other. The second region 2021 is arranged between the first region 2020 and the third region 2022. The third region 2022 is arranged between the second region 2021 and the fourth region 2023. The first region 2020 is electrically connected to the second doped area of the diode 200. The second region 2021 is electrically connected to the first doped area of the diode 200 and the first terminal of the voltage clamping component 201. The fourth region 2023 is electrically connected to the second terminal of the voltage clamping component 201. There is no capacitive component electrically connected between the second region 2021 and the first doped area of the diode 200. The second doped area of the diode 200 and the first region 2020 are electrically connected to a first pin 203. The second terminal of the voltage clamping component 201 and the fourth region 2023 are electrically connected to a second pin 204. In the first embodiment, the first conductivity type is an N type and the second conductivity type is a P type. The voltage clamping component 201 may be a Zener diode, an NPN bipolar junction transistor whose base is electrically floating, an NPN bipolar junction transistor whose emitter is coupled to its base, a PNP bipolar junction transistor whose base is electrically floating, or a PNP bipolar junction transistor whose emitter is coupled to its base. In such a case, the anode of the Zener diode, the collector of the PNP bipolar junction transistor, or the emitter of the NPN bipolar junction transistor is electrically connected to the second pin 204 and the fourth region 2023. The cathode of the Zener diode, the emitter of the PNP bipolar junction transistor, or the collector of the NPN bipolar junction transistor is electrically connected to the second region 2021 of the electronic component 202 and the first doped area of the diode 200. Since the electronic component 202 is a multi-junction component, the electrostatic discharge protection device 2 has low parasitic capacitance.

When the first pin 203 receives a positive pulse voltage and the second pin 204 receives a reference voltage lower than the positive pulse voltage, an electrostatic discharge current flows from the first pin 203 to the second pin 204 through the diode 200 and the voltage clamping component 201. Since the second region 2021 is electrically connected to the first doped area of the diode 200 and there is no capacitive component electrically connected between the second region 2021 and the first doped area of the diode 200, the reversed junction voltage between the first region 2020 and the second region 2021 is clamped by the forward biased voltage of the diode 200 and the reversed junction voltage between the first region 2020 and the second region 2021 is low. Hence, the junction capacitance formed by the first region 2020 and the second region 2021 has the characteristic of slightly capacitance-voltage variation in order to achieve low harmonic distortion.

When the first pin 203 receives a negative pulse voltage and the second pin 204 receives a reference voltage higher than the negative pulse voltage, a first electrostatic discharge current flows from the second pin 204 to the first pin 203 through the voltage clamping component 201, the second region 2021, and the first region 2020 and a second electrostatic discharge current flows from the second pin 204 to the first pin 203 through the electronic component 202. Since the first electrostatic discharge current is generated due to a low trigger voltage, the voltage clamping component 201 can help trigger on the electronic component 202 such that the electrostatic discharge protection device 2 has low trigger voltage. In addition, because the second region 2021 is electrically connected to the first doped area of the diode 200 and there is no capacitive component electrically connected between the second region 2021 and the first doped area of the diode 200, the reversed junction voltage of the diode 200 is clamped by the forward biased voltage of the first region 2020 and the second region 2021 and the reversed junction voltage of the diode 200 is low. The junction capacitance formed by the diode 200 has the characteristic of slightly capacitance-voltage variation in order to achieve low harmonic distortion.

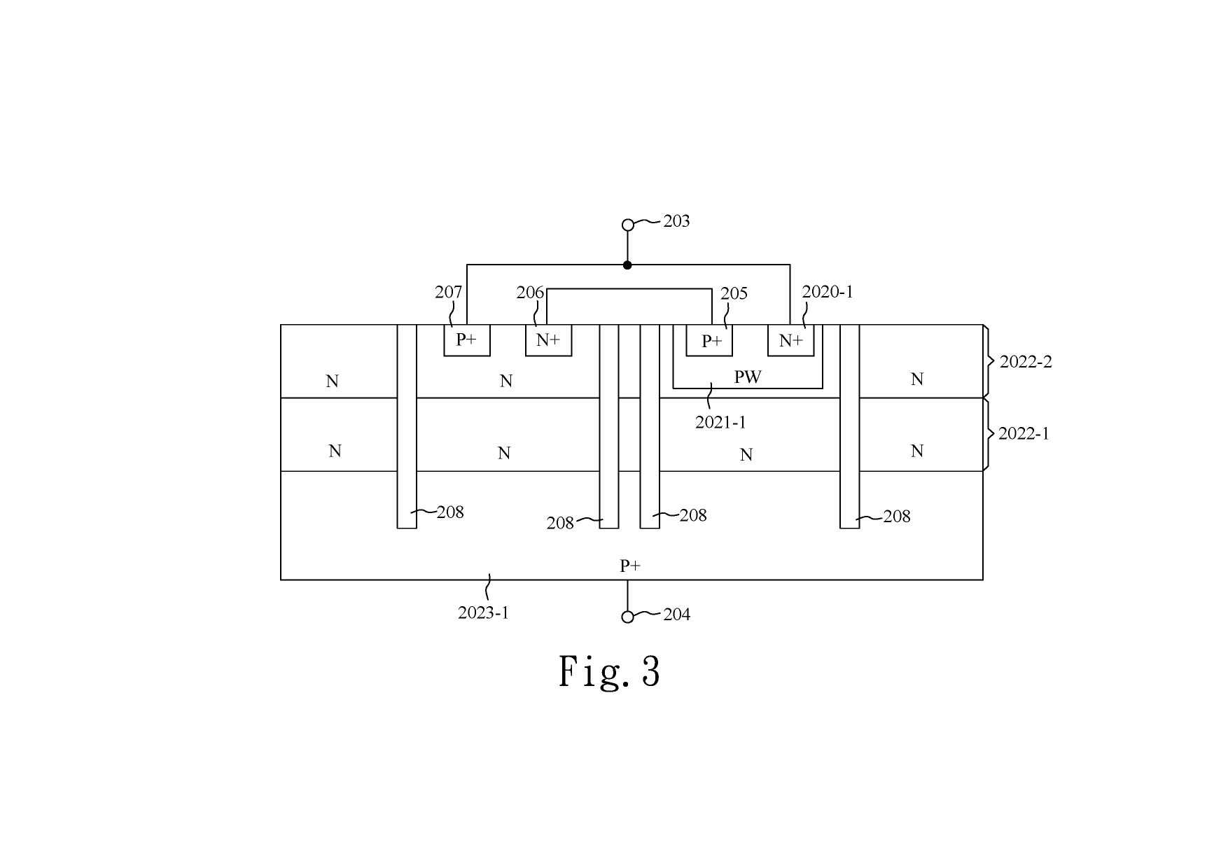

FIG. 3 is a cross-sectional view of an electrostatic discharge protection device according to a second embodiment of the present invention. Referring to FIG. 3 and FIG. 2, the second embodiment of the electrostatic discharge protection device 2 will be introduced as follows. The fourth region 2023 is implemented with a heavily-doped region 2023-1. The third region 2022 is implemented with a first epitaxial region 2022-1 and a second epitaxial region 2022-2. The second region 2021 is implemented with a first doped well 2021-1. The first region 2020 is implemented with a first heavily-doped area 2020-1. The first epitaxial region 2022-1 and the second epitaxial region 2022-2 are sequentially formed on the heavily-doped region 2023-1. The first doped well 2021-1 is formed in the second epitaxial region 2022-2. The first heavily-doped area 2020-1 and a second heavily-doped area 205 of the second conductivity type are formed in the first doped well 2021-1. A third heavily-doped area 206 of the first conductivity type and a fourth heavily-doped area 207 of the second conductivity type are formed in the second epitaxial region 2022-2. The second heavily-doped area 205 is electrically connected to the third heavily-doped area 206. The first heavily-doped area 2020-1 is electrically connected to the fourth heavily-doped area 207. The first doped area of the diode 200 is implemented with the second epitaxial region 2022-2 and the third heavily-doped area 206. The second doped area of the diode 200 is implemented with the fourth heavily-doped area 207. The voltage clamping component 201 is implemented with the heavily-doped region 2023-1 and the first epitaxial region 2022-1. Thus, the voltage clamping component 201 is implemented with a Zener diode. The first heavily-doped area 2020-1 and the fourth heavily-doped area 207 are electrically connected to the first pin 203. The heavily-doped region 2023-1 is electrically connected to the second pin 204.

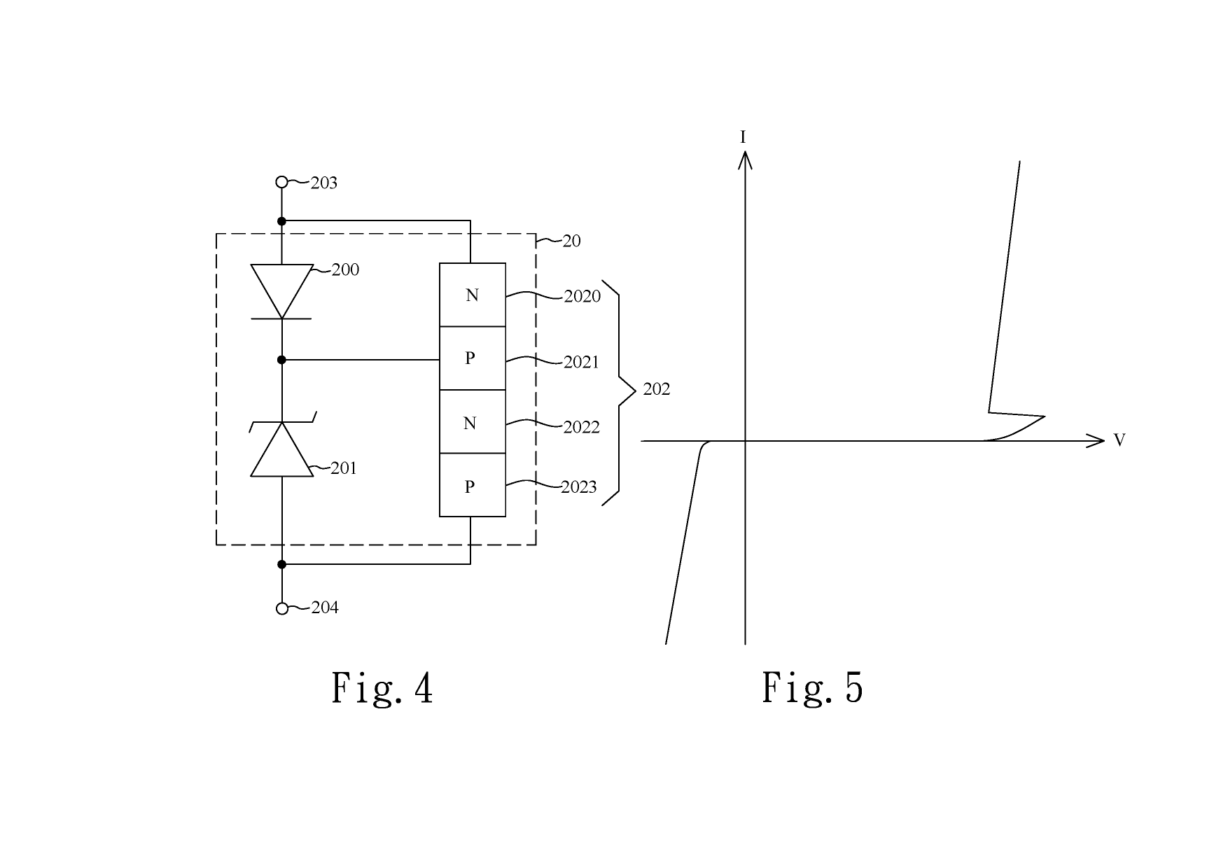

FIG. 4 is a schematic diagram illustrating an equivalent circuit of the electrostatic discharge protection device ofFIG. 3 .FIG. 5 is a schematic diagram illustrating a current-voltage curve of the electrostatic discharge protection device ofFIG. 3 . Referring to FIG. 3,FIG. 4 , and FIG. 5, the electrostatic discharge protection device 2 is a unidirectional electrostatic discharge device. The current-voltage curve has a snapback phenomenon when the first pin 203 receives a positive pulse voltage and the second pin 204 receives a reference voltage lower than the positive pulse voltage. When the concentration of the second epitaxial region 2022-2 is lighter, the snapback phenomenon of the current-voltage curve is more serious. The doping concentration of the first epitaxial region 2022-1 is greater than or equal to that of the second epitaxial region 2022-2. When the first doped well 2021-1 is a lightly-doped well and the second epitaxial region 2022-2 is also a lightly-doped epitaxial region, the electrostatic discharge protection device 2 has lower parasitic capacitance. In some embodiments of the present invention, the electrostatic discharge protection device 2 further includes two isolation structures 208 formed in the heavily-doped region 2023-1, the first epitaxial region 2022-1, and the second epitaxial region 2022-2. The isolation structures 208 include insulation materials. One of the isolation structures 208 surrounds the first doped well 2021-1, the first heavily-doped area 2020-1, and the second heavily-doped area 205. Another of the isolation structures 208 surrounds the third heavily-doped area 206 and the fourth heavily-doped area 207.

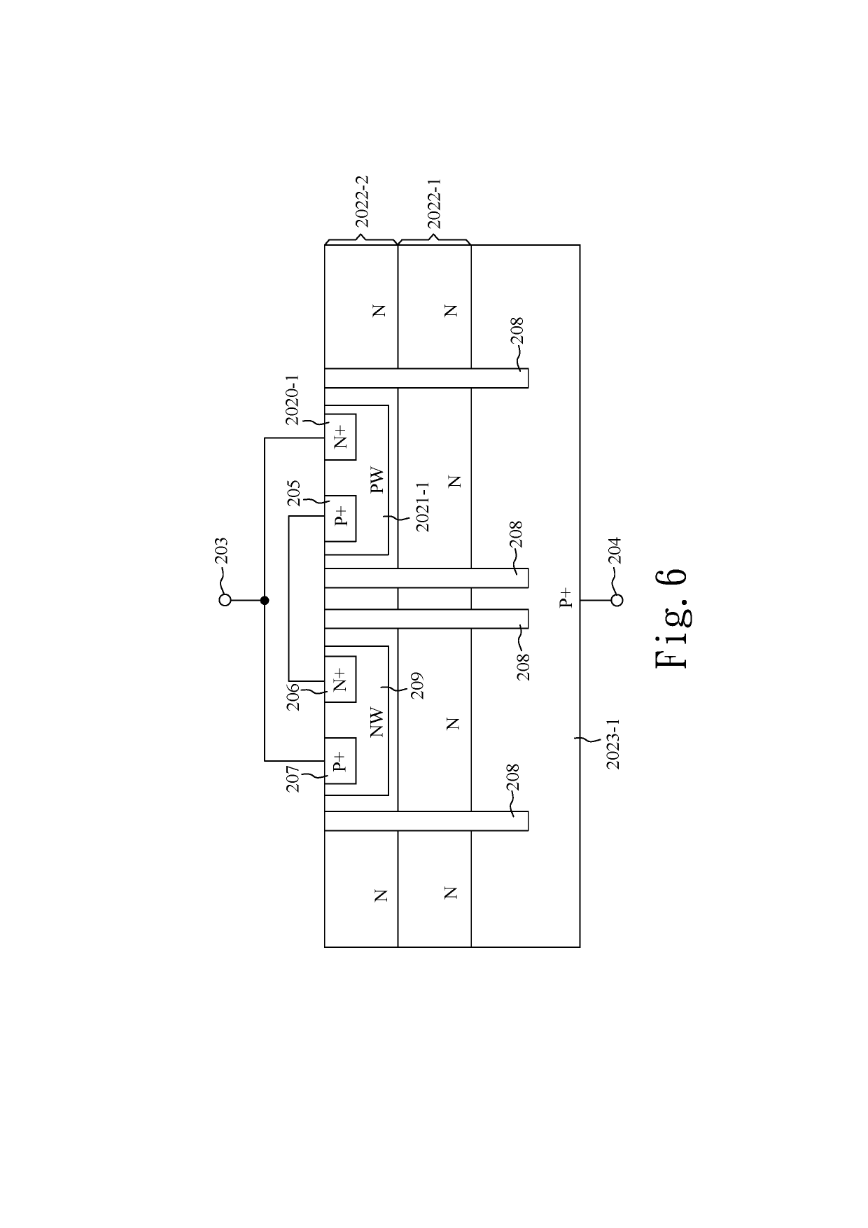

FIG. 6 is a cross-sectional view of an electrostatic discharge protection device according to a third embodiment of the present invention. Referring toFIG. 6 and FIG. 2, the third embodiment of the electrostatic discharge protection device 2 will be introduced as follows. The fourth region 2023 is implemented with a heavily-doped region 2023-1. The third region 2022 is implemented with a first epitaxial region 2022-1 and a second epitaxial region 2022-2. The second region 2021 is implemented with a first doped well 2021-1. The first region 2020 is implemented with a first heavily-doped area 2020-1. The first epitaxial region 2022-1 and the second epitaxial region 2022-2 are sequentially formed on the heavily-doped region 2023-1. The first doped well 2021-1 and a second doped well 209 of the first conductivity type are formed in the second epitaxial region 2022-2. The first heavily-doped area 2020-1 and a second heavily-doped area 205 of the second conductivity type are formed in the first doped well 2021-1. A third heavily-doped area 206 of the first conductivity type and a fourth heavily-doped area 207 of the second conductivity type are formed in the second doped well 209. The second heavily-doped area 205 is electrically connected to the third heavily-doped area 206. The first heavily-doped area 2020-1 is electrically connected to the fourth heavily-doped area 207. The first doped area of the diode 200 is implemented with the second doped well 209 and the third heavily-doped area 206. The second doped area of the diode 200 is implemented with the fourth heavily-doped area 207. The voltage clamping component 201 is implemented with the heavily-doped region 2023-1, the first epitaxial region 2022-1, and the second epitaxial region 2022-2. The first heavily-doped area 2020-1 and the fourth heavily-doped area 207 are electrically connected to the first pin 203. The heavily-doped region 2023-1 is electrically connected to the second pin 204. The doping concentration of the first epitaxial region 2022-1 is greater than or equal to that of the second epitaxial region 2022-2. When the first doped well 2021-1 and the second doped well 209 are lightly -doped wells, the electrostatic discharge protection device 2 has lower parasitic capacitance. In some embodiments of the present invention, the electrostatic discharge protection device 2 further includes two isolation structures 208 formed in the heavily-doped region 2023-1, the first epitaxial region 2022-1, and the second epitaxial region 2022-2. The isolation structures 208 include insulation materials. One of the isolation structures 208 surrounds the first doped well 2021-1, the first heavily-doped area 2020-1, and the second heavily-doped area 205. Another of the isolation structures 208 surrounds the third heavily-doped area 206, the fourth heavily-doped area 207, and the second doped well 209.

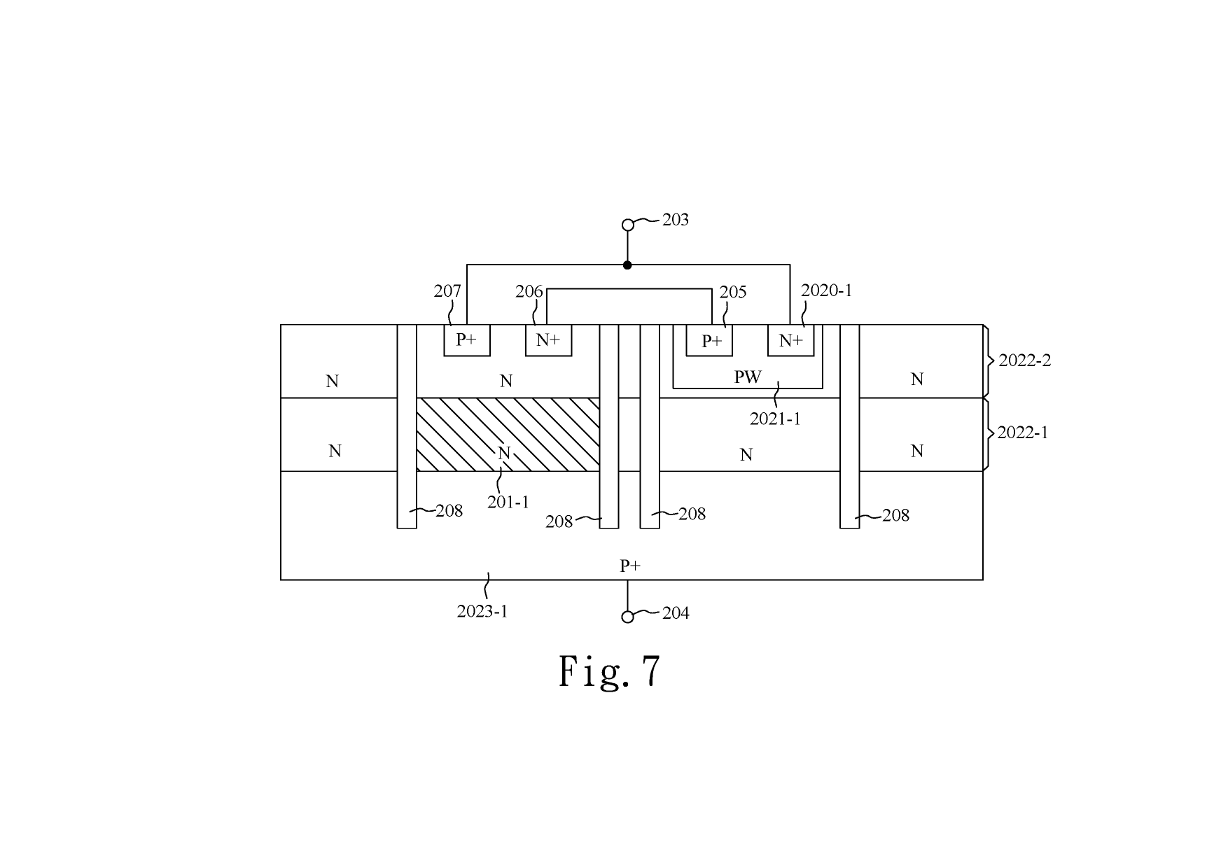

FIG. 7 is a cross-sectional view of an electrostatic discharge protection device according to a fourth embodiment of the present invention. Referring to FIG. 2, FIG. 7, and FIG. 3, the fourth embodiment of the electrostatic discharge protection device 2 will be introduced as follows. Compared with the second embodiment, the fourth embodiment further includes a buried region 201-1 of the first conductivity type formed in the first epitaxial region 2022-1 and formed between the fourth heavily-doped area 207 and the heavily-doped region 2023-1. The doping concentration of the buried region 201-1 is greater than that of the first epitaxial region 2022-1. The buried region 201-1 is used to adjust the breakdown voltage of a Zener diode formed by the buried region 201-1 and the heavily-doped region 2023-1. Since the doping concentration of the buried region 201-1 is greater than that of the first epitaxial region 2022-1, the turn-on resistance of the diode 200 connected in series to the Zener diode formed by the buried region 201-1 and the heavily-doped region 2023-1 can be reduced.

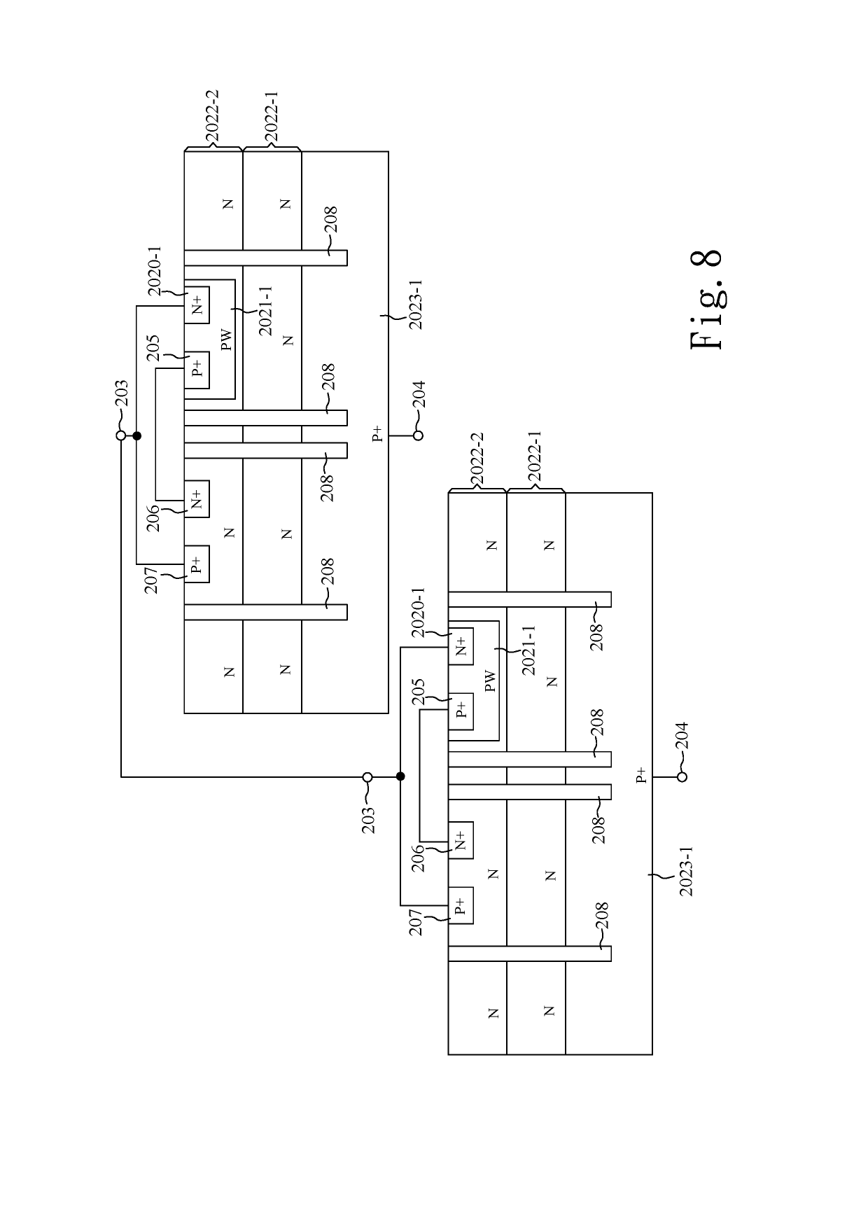

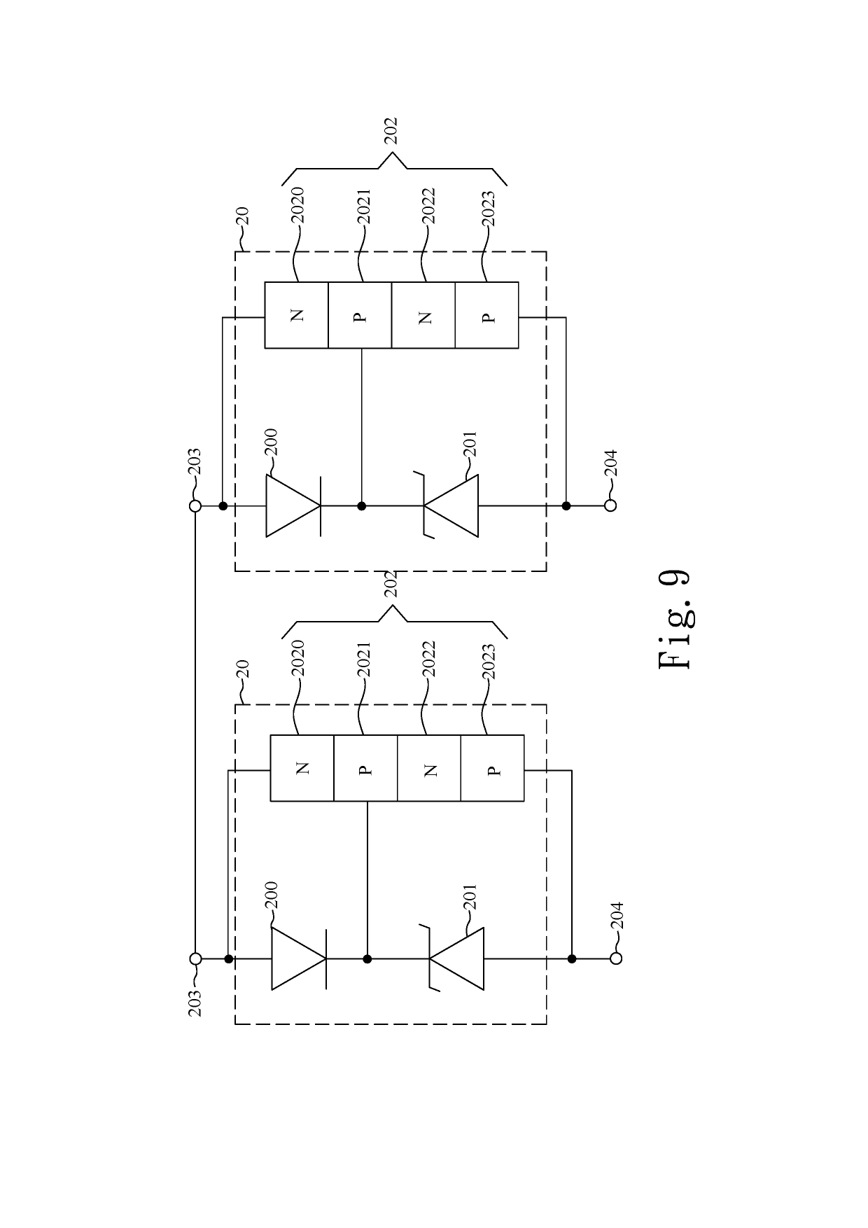

FIG. 8 is a cross-sectional view of an electrostatic discharge protection device according to a fifth embodiment of the present invention.FIG. 9 is a schematic diagram illustrating an equivalent circuit of the electrostatic discharge protection device of FIG. 8. Referring to FIG. 2, FIG. 8, and FIG. 9, the fifth embodiment of the electrostatic discharge protection device 2 will be introduced as follows. Compared with the second embodiment, the fifth embodiment uses two voltage clamping devices 20. The first pin 203 of one of the two voltage clamping devices 20 is electrically connected to the first pin 203 of another of the two voltage clamping devices 20.

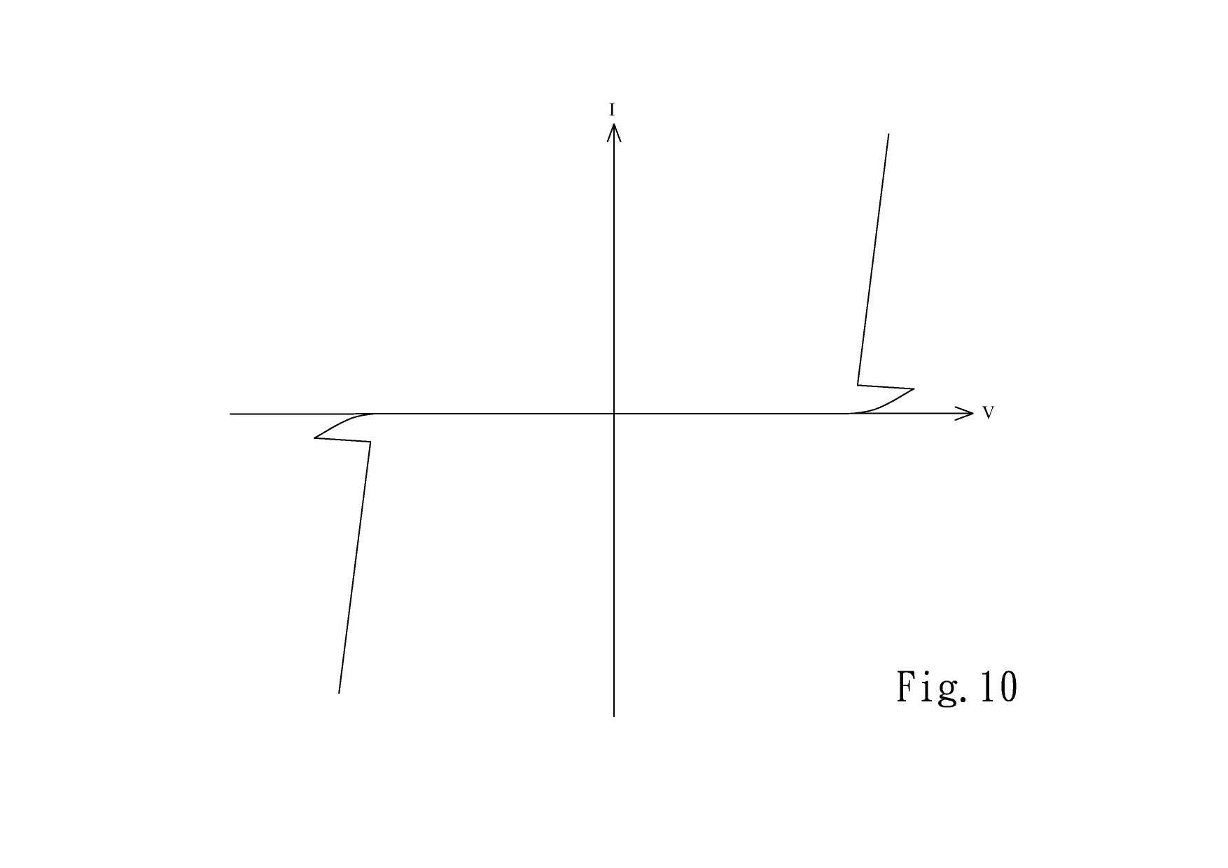

FIG. 10 is a schematic diagram illustrating a current-voltage curve of the electrostatic discharge protection device of FIG. 8. Referring to FIG. 9 and FIG. 10, the electrostatic discharge protection device 2 is a bidirectional electrostatic discharge device. When one first pin 203 receive a pulse voltage and another first pin 203 receives a reference voltage lower than the pulse voltage, the current-voltage curve has a snapback phenomenon.

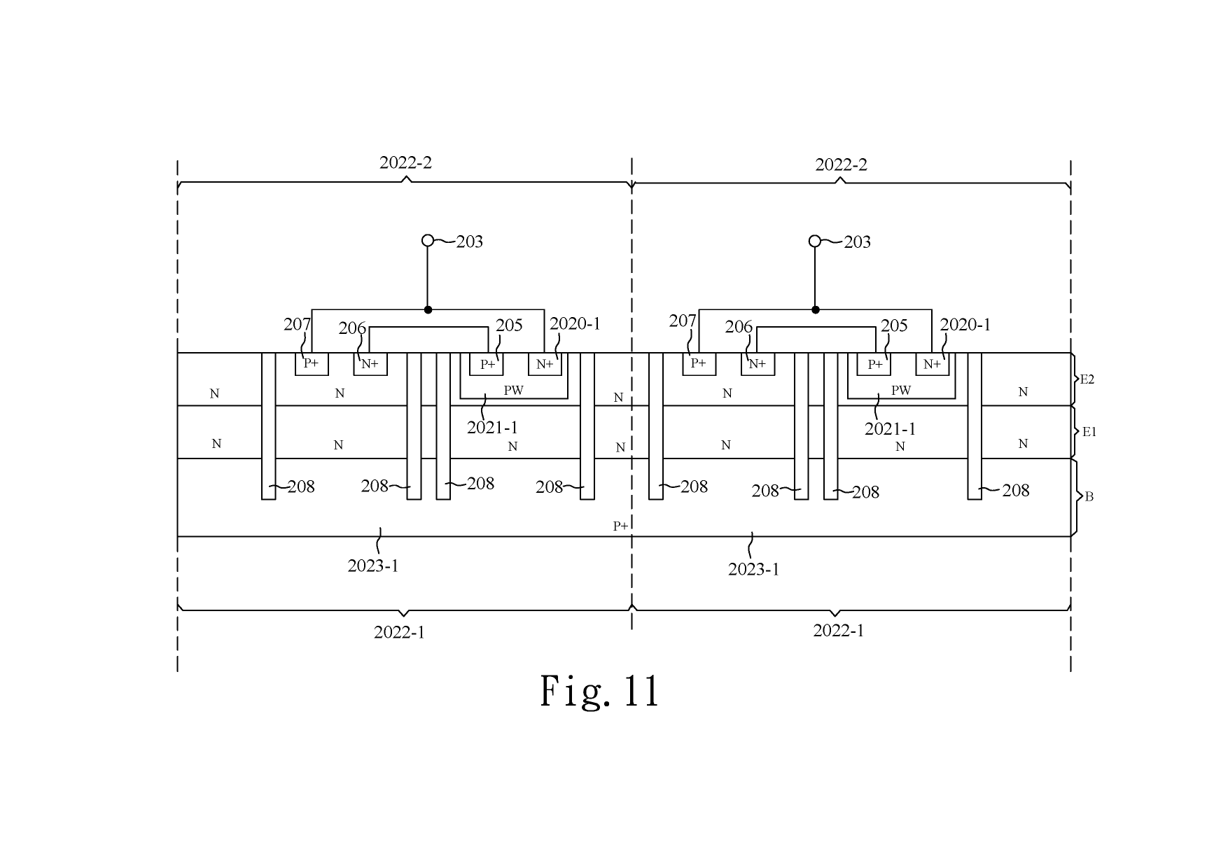

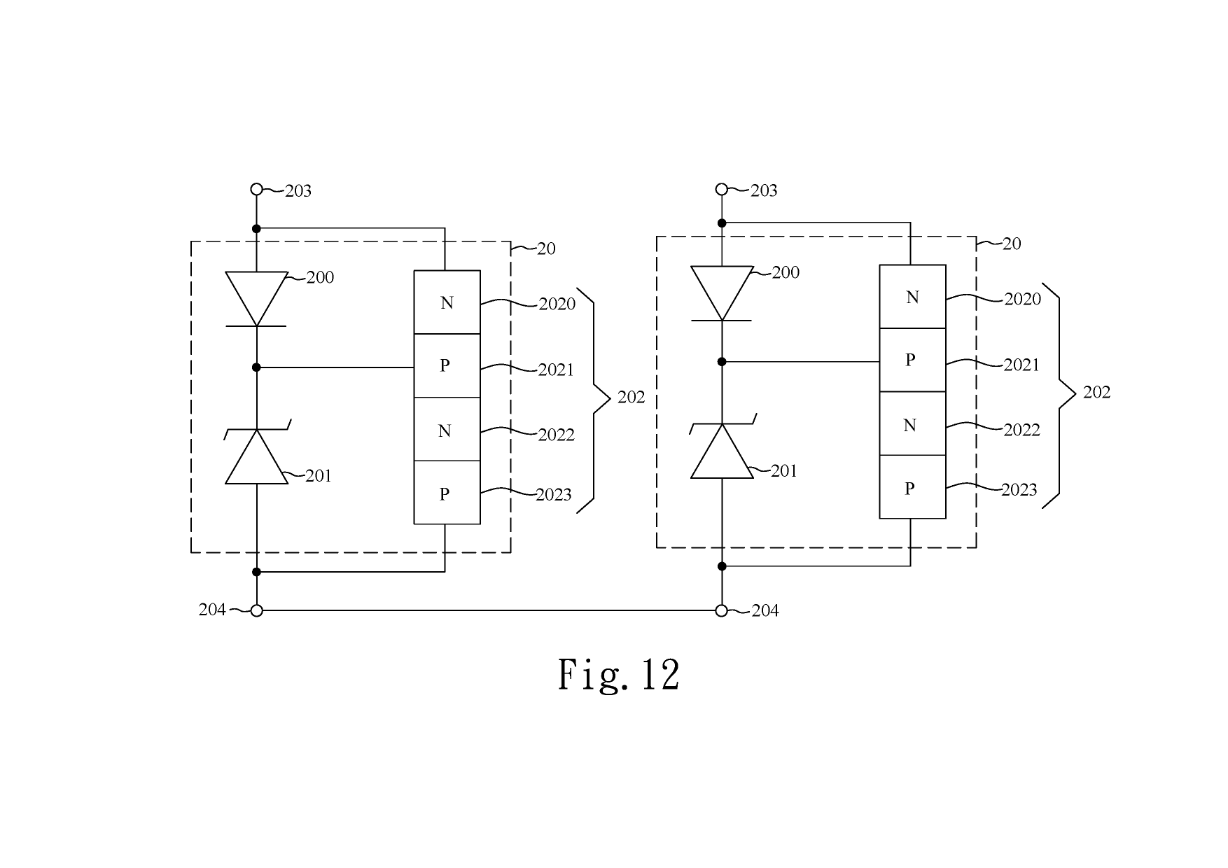

FIG. 11 is a cross-sectional view of an electrostatic discharge protection device according to a sixth embodiment of the present invention. FIG. 12 is a schematic diagram illustrating an equivalent circuit of the electrostatic discharge protection device of FIG. 11. Referring to FIG. 2, FIG. 11, and FIG. 12, the sixth embodiment of the electrostatic discharge protection device 2 will be introduced as follows. Compared with the second embodiment, the sixth embodiment uses two voltage clamping devices 20 and the second pin 204 of one of the two voltage clamping devices 20 is electrically connected to the second pin 204 of another of the two voltage clamping devices 20. In the sixth embodiment, the heavily-doped regions 2023-1 of the two voltage clamping devices 20 are different regions of a heavily-doped substrate B, the first epitaxial regions 2022-1 of the two voltage clamping devices 20 are different regions of a first epitaxial layer E1, and the second epitaxial regions 2022-2 of the two voltage clamping devices 20 are different regions of a second epitaxial layer E2. The first heavily-doped area 2020-1 and the fourth heavily-doped area 207 of one of the two voltage clamping devices 20 are electrically connected to a first pin 203 and the first heavily-doped area 2020-1 and the fourth heavily-doped area 207 of another of the two voltage clamping devices 20 are electrically connected to a second pin 204’. Like the fifth embodiment, the electrostatic discharge protection device 2 of the sixth embodiment is a bidirectional electrostatic discharge device.

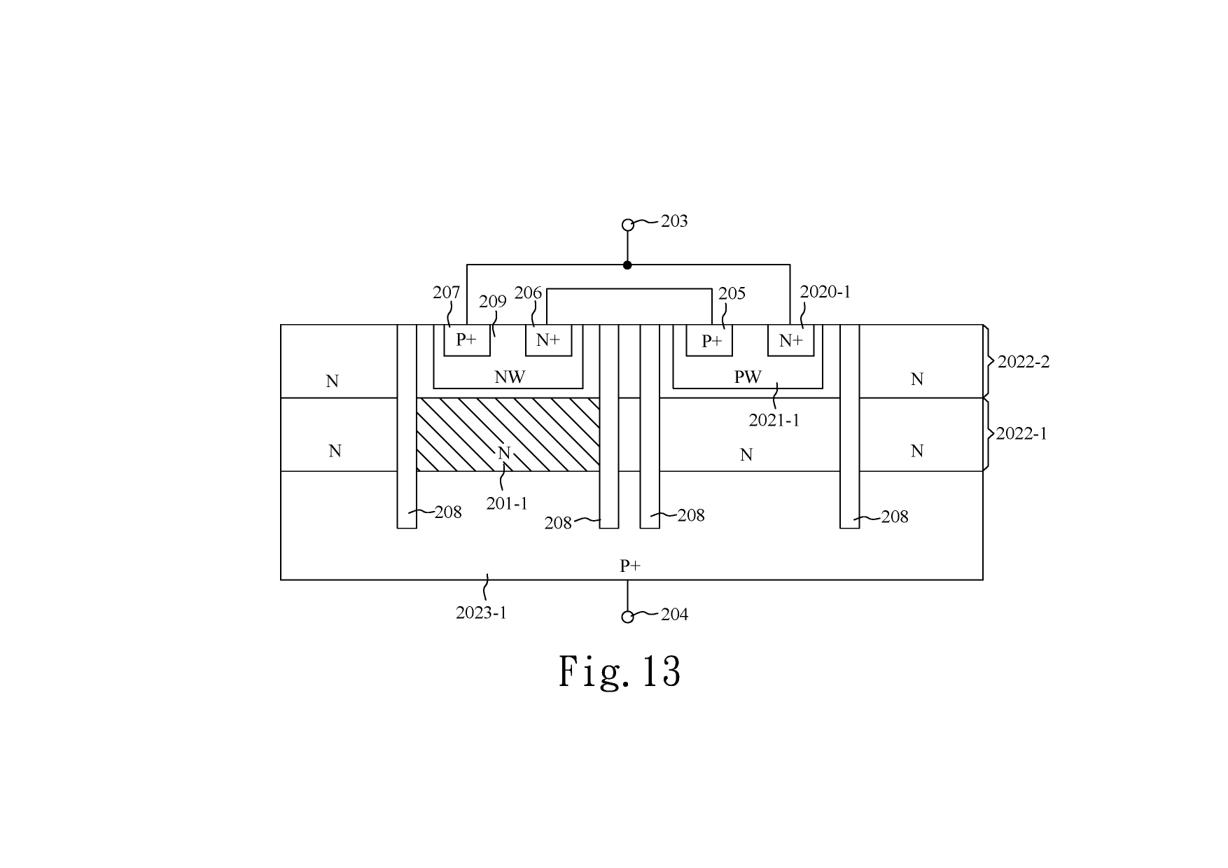

FIG. 13 is a cross-sectional view of an electrostatic discharge protection device according to a seventh embodiment of the present invention. Referring to FIG. 2, FIG. 6 and FIG. 13, the seventh embodiment of the electrostatic discharge protection device 2 will be introduced as follows. Compared with the third embodiment, the seventh embodiment further includes a buried region 201-1 of the first conductivity type formed in the first epitaxial region 2022-1 and formed between the fourth heavily-doped area 207 and the heavily-doped region 2023-1. The doping concentration of the buried region 201-1 is greater than that of the first epitaxial region 2022-1. The buried region 201-1 is used to adjust the breakdown voltage of a Zener diode formed by the buried region 201-1 and the heavily-doped region 2023-1. Since the doping concentration of the buried region 201-1 is greater than that of the first epitaxial region 2022-1, the turn-on resistance of the diode 200 connected in series to the Zener diode formed by the buried region 201-1 and the heavily-doped region 2023-1 can be reduced.

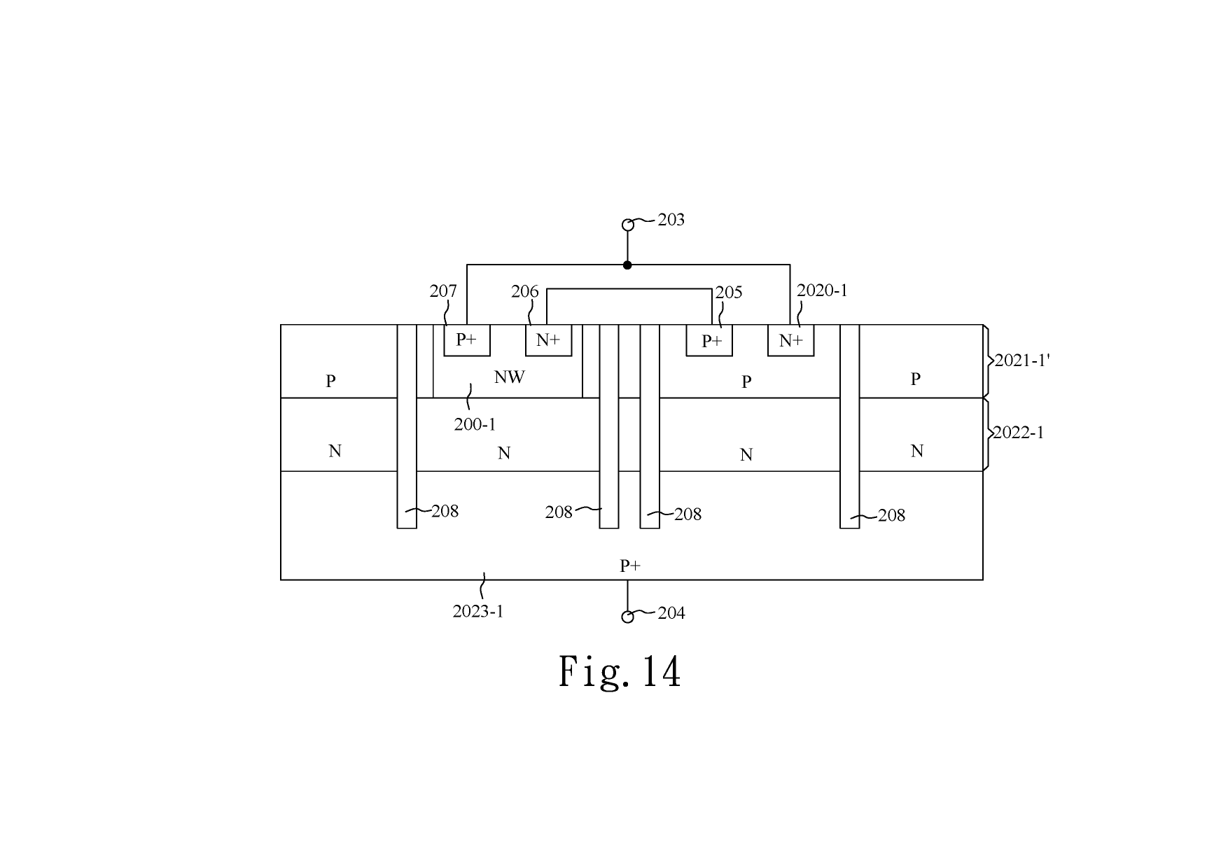

FIG. 14 is a cross-sectional view of an electrostatic discharge protection device according to an eighth embodiment of the present invention. Referring to FIG. 2 and FIG. 14, the eighth embodiment of the electrostatic discharge protection device 2 will be introduced as follows. The fourth region 2023 is implemented with a heavily-doped region 2023-1. The third region 2022 is implemented with a first epitaxial region 2022-1. The second region 2021 is implemented with a second epitaxial region 2021-1’. The first region 2020 is implemented with a first heavily-doped area 2020-1. The first epitaxial region 2022-1 and the second epitaxial region 2021-1’ are sequentially formed on the heavily-doped region 2023-1. The first heavily-doped area 2020-1 and a second heavily-doped area 205 of the second conductivity type are formed in the second epitaxial region 2021-1’. A third heavily-doped area 206 of the first conductivity type and a fourth heavily-doped area 207 of the second conductivity type are formed in a first doped well 200-1 of the first conductivity type. The first doped well 200-1 is formed in the second epitaxial region 2021-1’. The second heavily-doped area 205 is electrically connected to the third heavily-doped area 206. The first heavily-doped area 2020-1 is electrically connected to the fourth heavily-doped area 207. The first doped area of the diode 200 is implemented with the first doped well 200-1 and the third heavily-doped area 206. The second doped area of the diode 200 is implemented with the fourth heavily-doped area 207. The voltage clamping component 201 is implemented with the second epitaxial region 2021-1’, the heavily-doped region 2023-1, and the first epitaxial region 2022-1. Particularly, when the bottom of the first doped well 200-1 touches the first epitaxial region 2022-1, the voltage clamping component 201 is implemented with the heavily-doped region 2023-1 and the first epitaxial region 2022-1 that form a Zener diode. The first heavily-doped area 2020-1 and the fourth heavily-doped area 207 are electrically connected to the first pin 203. The heavily-doped region 2023-1 is electrically connected to the second pin 204.

In some embodiments of the present invention, the electrostatic discharge protection device 2 further includes two isolation structures 208 formed in the heavily-doped region 2023-1, the first epitaxial region 2022-1, and the second epitaxial region 2021-1’. The isolation structures 208 include insulation materials. One of the isolation structures 208 surrounds the first doped well 200-1, the third heavily-doped area 206, and the fourth heavily-doped area 207. Another of the isolation structures 208 surrounds the first heavily-doped area 2020-1 and the second heavily-doped area 205.

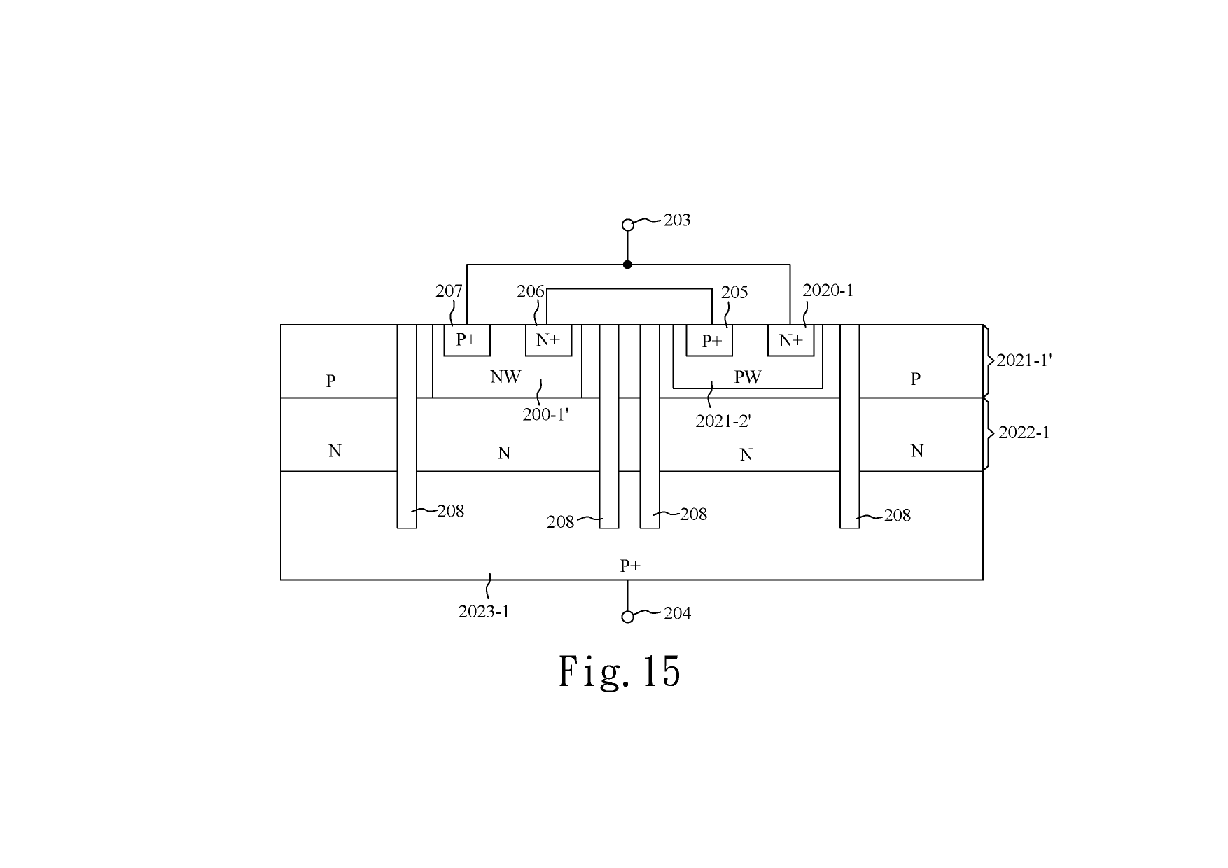

FIG. 15 is a cross-sectional view of an electrostatic discharge protection device according to a ninth embodiment of the present invention. Referring to FIG. 15 and FIG. 2, the ninth embodiment of the electrostatic discharge protection device 2 will be introduced as follows. The fourth region 2023 is implemented with a heavily-doped region 2023-1. The third region 2022 is implemented with a first epitaxial region 2022-1. The second region 2021 is implemented with a second epitaxial region 2021-1’ and a first doped well 2021-2’. The first region 2020 is implemented with a first heavily-doped area 2020-1. The first epitaxial region 2022-1 and the second epitaxial region 2021-1’ are sequentially formed on the heavily-doped region 2023-1. The first heavily-doped area 2020-1 and a second heavily-doped area 205 of the second conductivity type are formed in the first doped well 2021-2’. A third heavily-doped area 206 of the first conductivity type and a fourth heavily-doped area 207 of the second conductivity type are formed in a second doped well 200-1’ of the first conductivity type. The first doped well 2021-2’ and the second doped well 200-1’ are formed in the second epitaxial region 2021-1’. The second heavily-doped area 205 is electrically connected to the third heavily-doped area 206. The first heavily-doped area 2020-1 is electrically connected to the fourth heavily-doped area 207. The first doped area of the diode 200 is implemented with the second doped well 200-1’ and the third heavily-doped area 206. The second doped area of the diode 200 is implemented with the fourth heavily-doped area 207. The voltage clamping component 201 is implemented with the second epitaxial region 2021-1’, the heavily-doped region 2023-1, and the first epitaxial region 2022-1. The first heavily-doped area 2020-1 and the fourth heavily-doped area 207 are electrically connected to a first pin 203. The heavily-doped region 2023-1 is electrically connected to a second pin 204. Particularly, the bottom of the second doped well 200-1’ touches the first epitaxial region 2022-1.

In some embodiments of the present invention, the electrostatic discharge protection device 2 further includes two isolation structures 208 formed in the heavily-doped region 2023-1, the first epitaxial region 2022-1, and the second epitaxial region 2021-1’. The isolation structures 208 include insulation materials. One of the isolation structures 208 surrounds the first doped well 2021-2’, the first heavily-doped area 2020-1, and the second heavily-doped area 205. Another of the isolation structures 208 surrounds the second doped well 200-1’, the third heavily-doped area 206 and the fourth heavily-doped area 207.

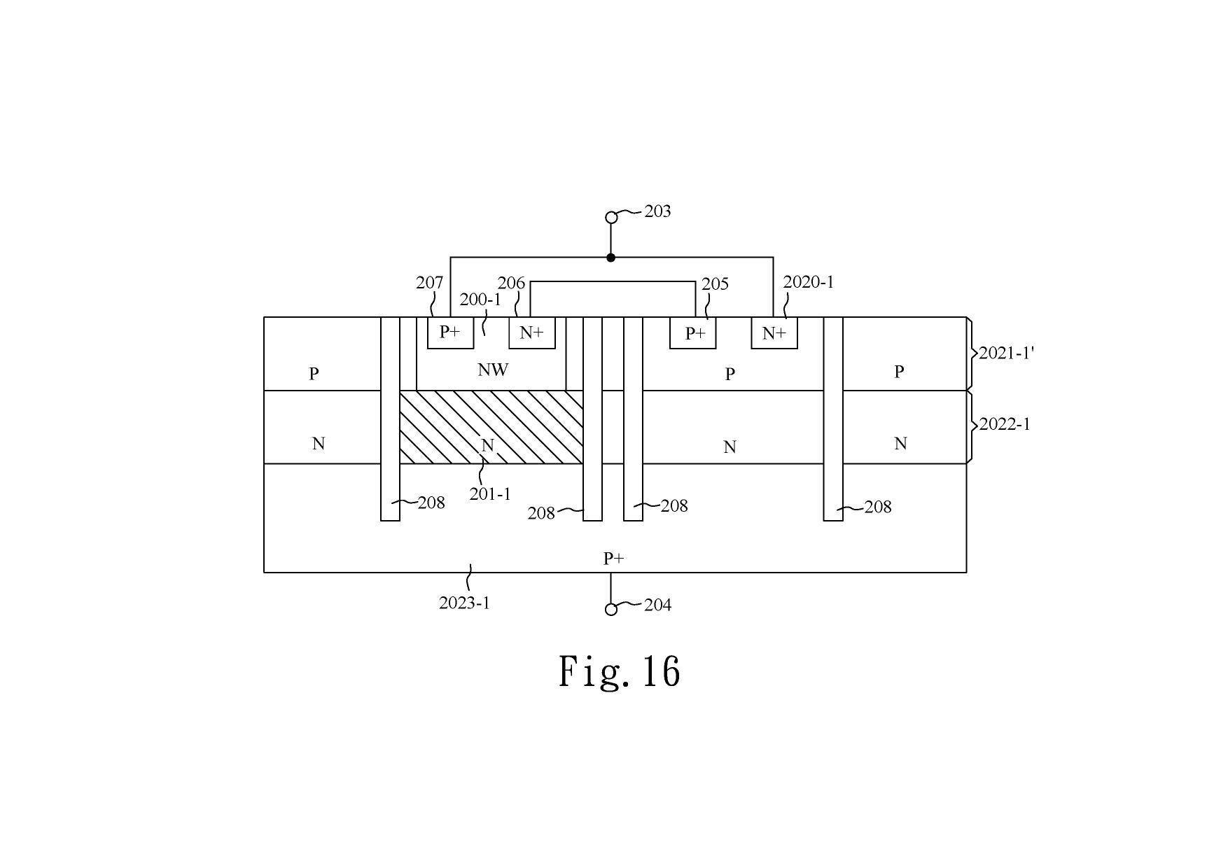

FIG. 16 is a cross-sectional view of an electrostatic discharge protection device according to a tenth embodiment of the present invention. Referring to FIG. 2, FIG. 14, and FIG. 16, the tenth embodiment of the electrostatic discharge protection device 2 will be introduced as follows. Compared with the eighth embodiment, the tenth embodiment further includes a buried region 201-1 of the first conductivity type formed in the first epitaxial region 2022-1 and formed between the fourth heavily-doped area 207 and the heavily-doped region 2023-1. The doping concentration of the buried region 201-1 is greater than that of the first epitaxial region 2022-1. The buried region 201-1 is used to adjust the breakdown voltage of a Zener diode formed by the buried region 201-1 and the heavily-doped region 2023-1. Since the doping concentration of the buried region 201-1 is greater than that of the first epitaxial region 2022-1, the turn-on resistance of the diode 200 connected in series to the Zener diode formed by the buried region 201-1 and the heavily-doped region 2023-1 can be reduced.

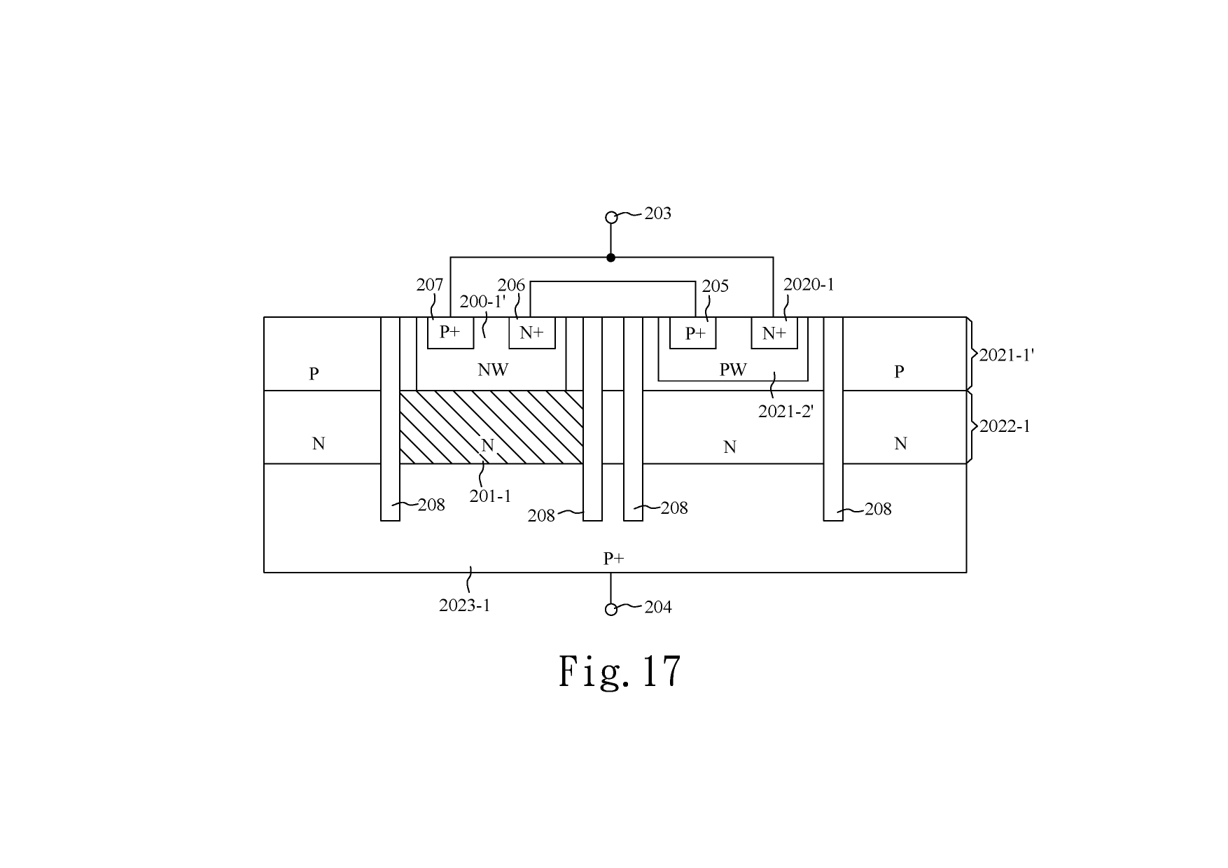

FIG. 17 is a cross-sectional view of an electrostatic discharge protection device according to an eleventh embodiment of the present invention. Referring toFIG. 2 , FIG. 15, and FIG. 17, the eleventh embodiment of the electrostatic discharge protection device 2 will be introduced as follows. Compared with the ninth embodiment, the eleventh embodiment further includes a buried region 201-1 of the first conductivity type formed in the first epitaxial region 2022-1 and formed between the fourth heavily-doped area 207 and the heavily-doped region 2023-1. The doping concentration of the buried region 201-1 is greater than that of the first epitaxial region 2022-1. The buried region 201-1 is used to adjust the breakdown voltage of a Zener diode formed by the buried region 201-1 and the heavily-doped region 2023-1. Since the doping concentration of the buried region 201-1 is greater than that of the first epitaxial region 2022-1, the turn-on resistance of the diode 200 connected in series to the Zener diode formed by the buried region 201-1 and the heavily-doped region 2023-1 can be reduced.

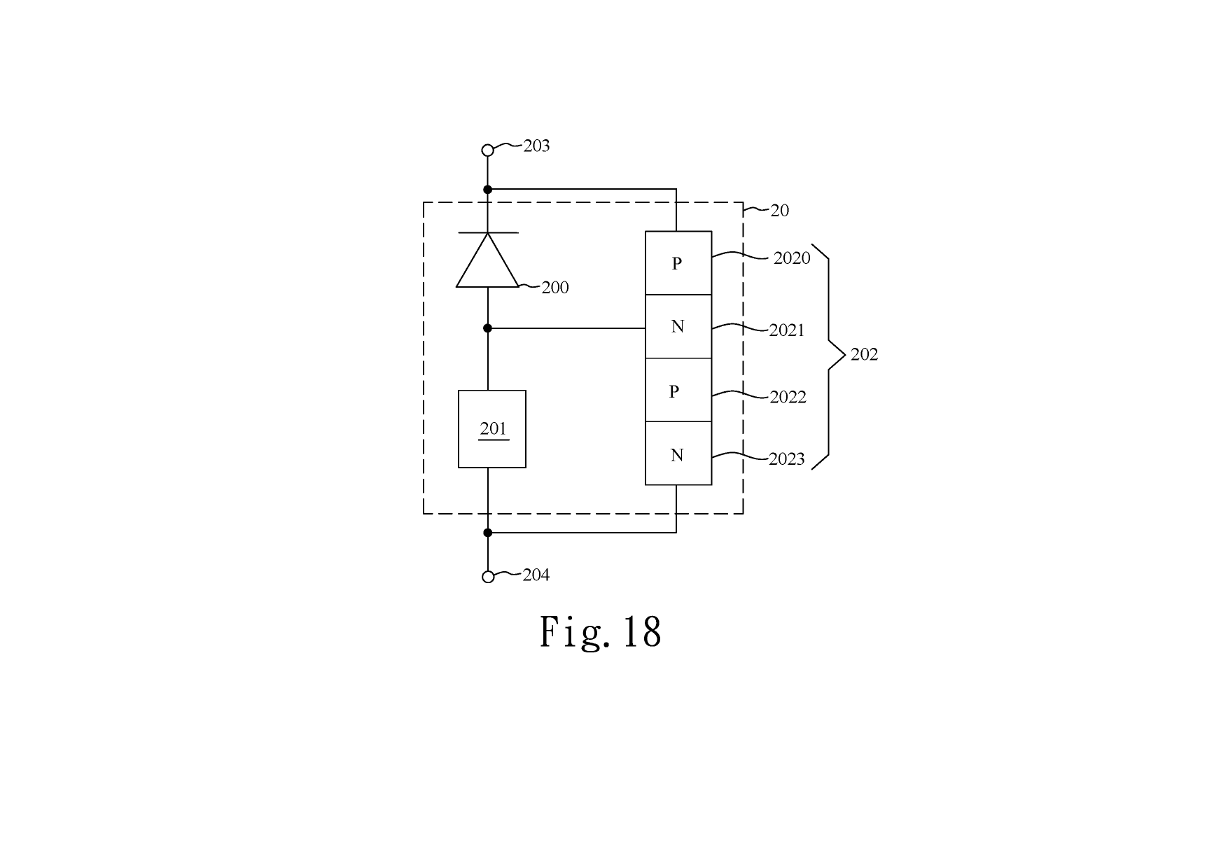

FIG. 18 is a schematic diagram illustrating an electrostatic discharge protection device according to a twelfth embodiment of the present invention. Referring to FIG. 18, the twelfth embodiment is different from the first embodiment in the conductivity type. In the twelfth embodiment, the first conductivity type is a P type and the second conductivity type is an N type. The voltage clamping component 201 may be a Zener diode, an NPN bipolar junction transistor whose base is electrically floating, an NPN bipolar junction transistor whose emitter is coupled to its base, a PNP bipolar junction transistor whose base is electrically floating, or a PNP bipolar junction transistor whose emitter is coupled to its base. In such a case, the cathode of the Zener diode, the emitter of the PNP bipolar junction transistor, or the collector of the NPN bipolar junction transistor is electrically connected to the second pin 204 and the fourth region 2023. The anode of the Zener diode, the collector of the PNP bipolar junction transistor, or the emitter of the NPN bipolar junction transistor is electrically connected to the second region 2021 of the electronic component 202 and the first doped area of the diode 200. The other structures of the embodiment ofFIG. 18 have been described previously so it will not be reiterated.

When the second pin 204 receives a reference voltage and the first pin 203 receives a negative pulse voltage lower than the reference voltage, an electrostatic discharge current flows from the second pin 204 to the first pin 203 through the voltage clamping component 201 and the diode 200. Since the second region 2021 is electrically connected to the first doped area of the diode 200 and there is no capacitive component electrically connected between the second region 2021 and the first doped area of the diode 200, the reversed junction voltage between the first region 2020 and the second region 2021 is clamped by the forward biased voltage of the diode 200 and the reversed junction voltage between the first region 2020 and the second region 2021 is low. Hence, the junction capacitance formed by the first region 2020 and the second region 2021 has the characteristic of slightly capacitance-voltage variation in order to achieve low harmonic distortion.

When the first pin 203 receives a positive pulse voltage and the second pin 204 receives a reference voltage lower than the positive pulse voltage, a first electrostatic discharge current flows from the first pin 203 to second the pin 204 through the first region 2020, the second region 2021, and the voltage clamping component 201 and a second electrostatic discharge current flows from the first pin 203 to the second pin 204 through the electronic component 202. Since the first electrostatic discharge current is generated due to a low trigger voltage, the voltage clamping component 201 can help trigger on the electronic component 202 such that the electrostatic discharge protection device 2 has low trigger voltage. In addition, because the second region 2021 is electrically connected to the first doped area of the diode 200 and there is no capacitive component electrically connected between the second region 2021 and the first doped area of the diode 200, the reversed junction voltage of the diode 200 is clamped by the forward biased voltage of the first region 2020 and the second region 2021 and the reversed junction voltage of the diode 200 is low. The junction capacitance formed by the diode 200 has the characteristic of slightly capacitance-voltage variation in order to achieve low harmonic distortion.

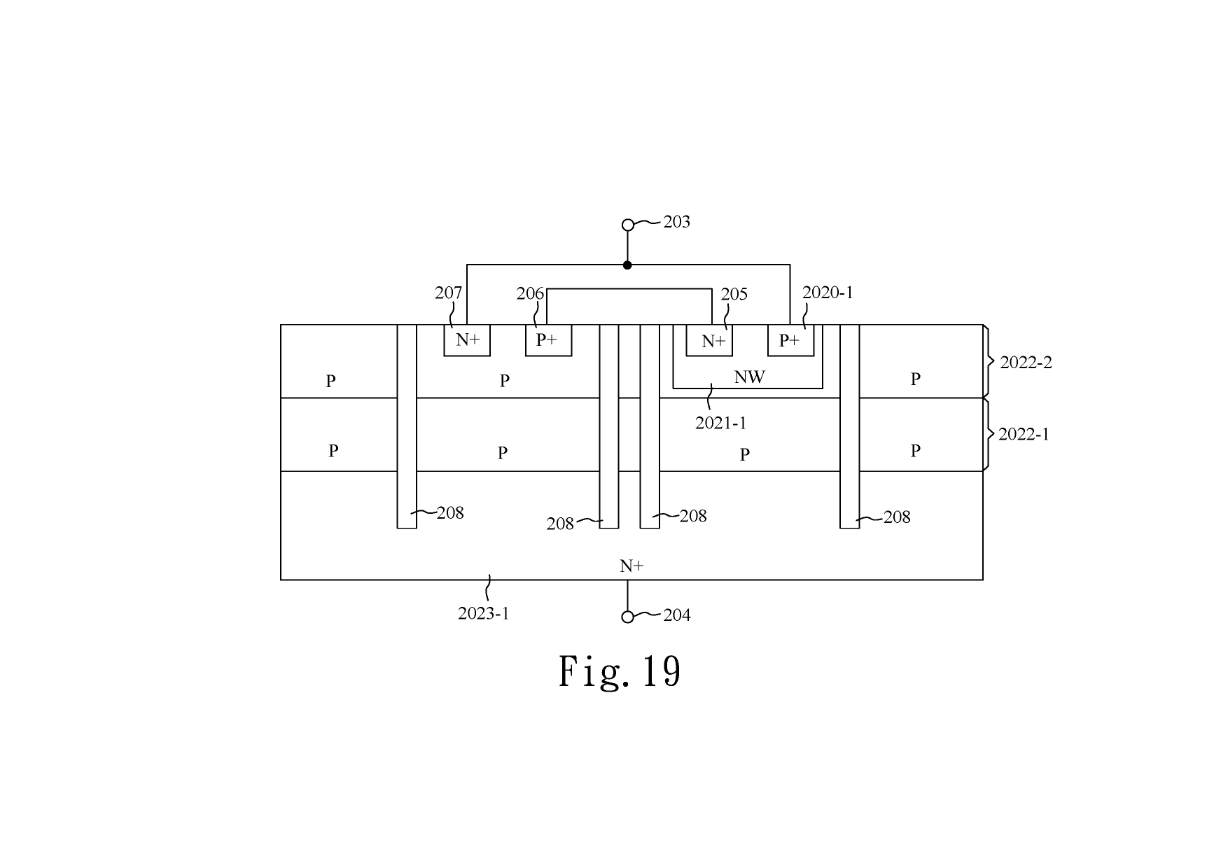

FIG. 19 is a cross-sectional view of an electrostatic discharge protection device according to a thirteenth embodiment of the present invention. Referring to FIG. 19, the thirteenth embodiment is different from the second embodiment in the conductivity type. In the thirteenth embodiment, the first conductivity type is a P type and the second conductivity type is an N type. The other structures of the embodiment of FIG. 19 have been described previously so it will not be reiterated.

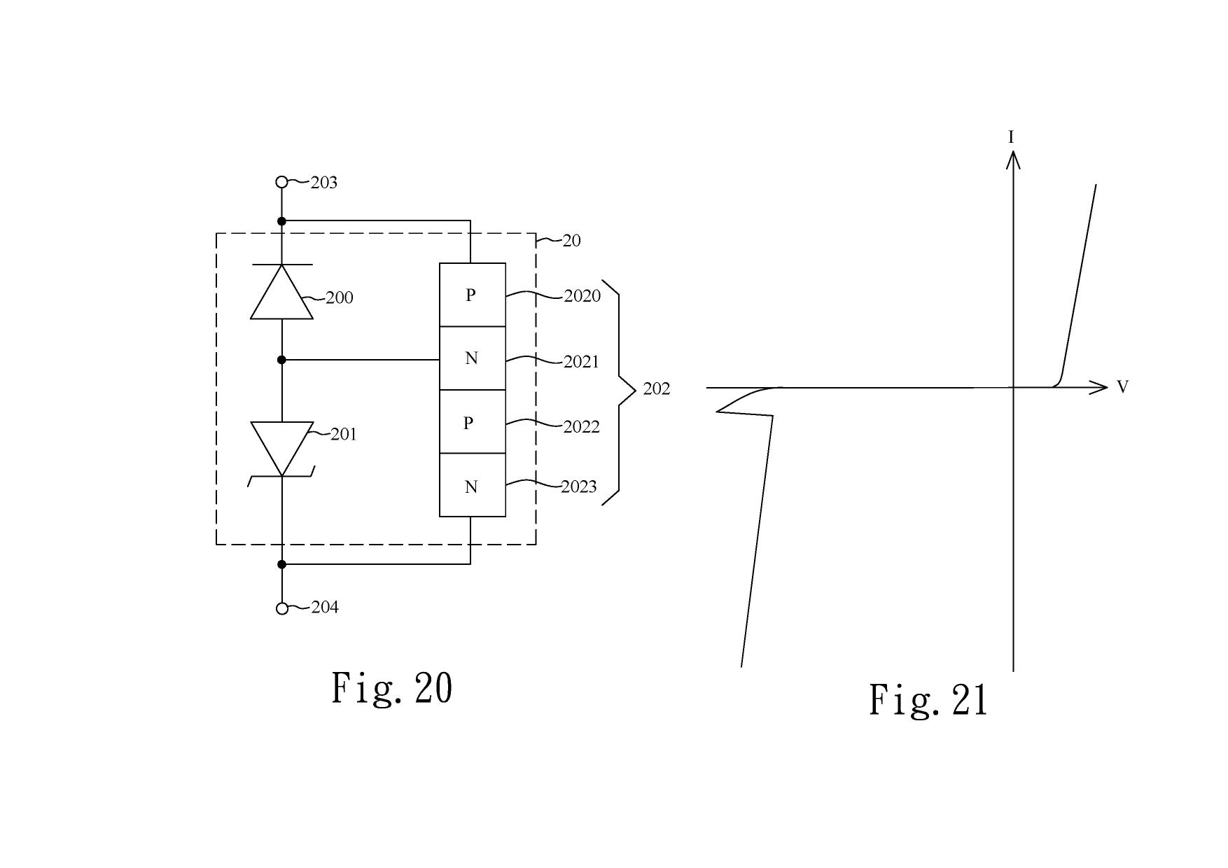

FIG. 20 is a schematic diagram illustrating an equivalent circuit of the electrostatic discharge protection device of FIG. 19. FIG. 21 is a schematic diagram illustrating a current-voltage curve of the electrostatic discharge protection device of FIG. 19. Referring to FIG. 19, FIG. 20, and FIG. 21, the electrostatic discharge protection device 2 is a unidirectional electrostatic discharge device. The current-voltage curve has a snapback phenomenon when the second pin 204 receives a reference voltage and the first pin 203 receives a negative voltage lower than the reference voltage. The other structures of the embodiment of FIG. 19 have been described previously so it will not be reiterated.

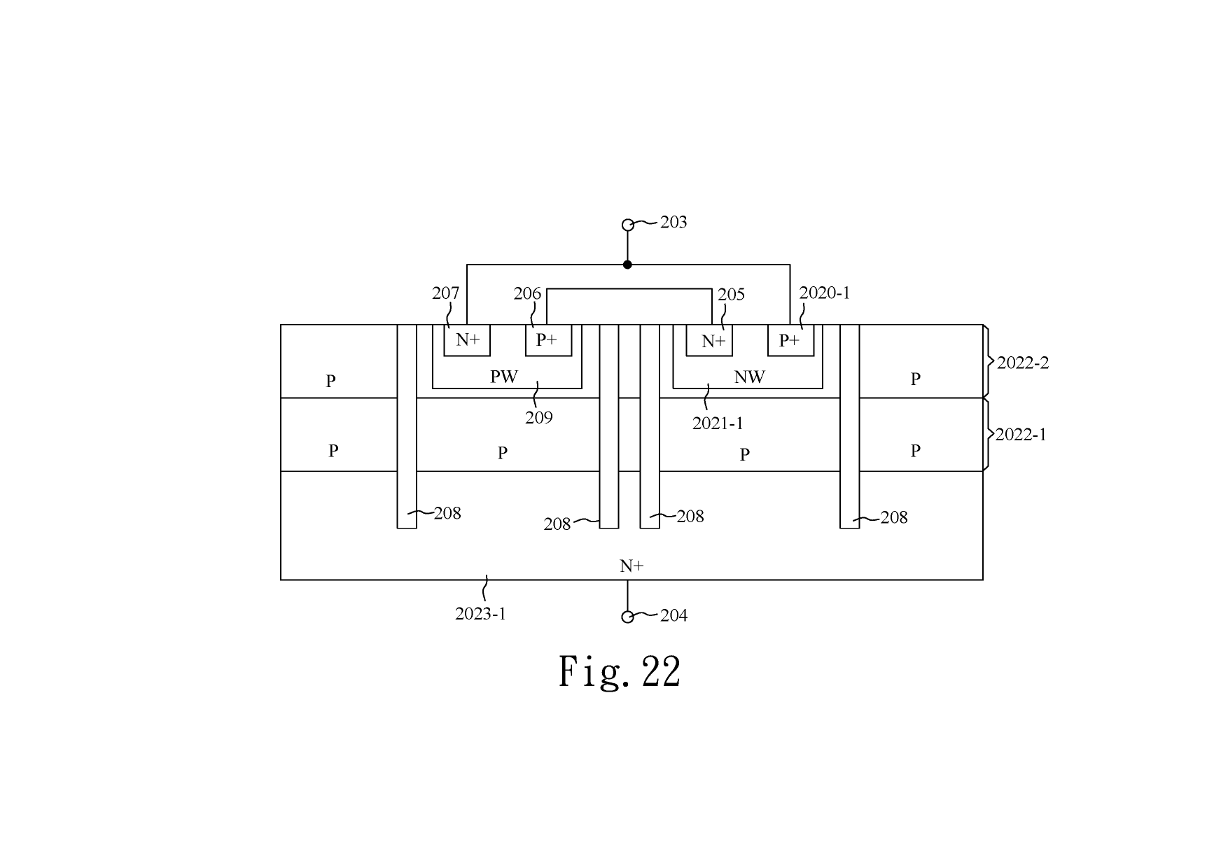

FIG. 22 is a cross-sectional view of an electrostatic discharge protection device according to a fourteenth embodiment of the present invention. Referring to FIG. 22, the fourteenth embodiment is different from the third embodiment in the conductivity type. In the fourteenth embodiment, the first conductivity type is a P type and the second conductivity type is an N type. The other structures of the embodiment of FIG. 22 have been described previously so it will not be reiterated.

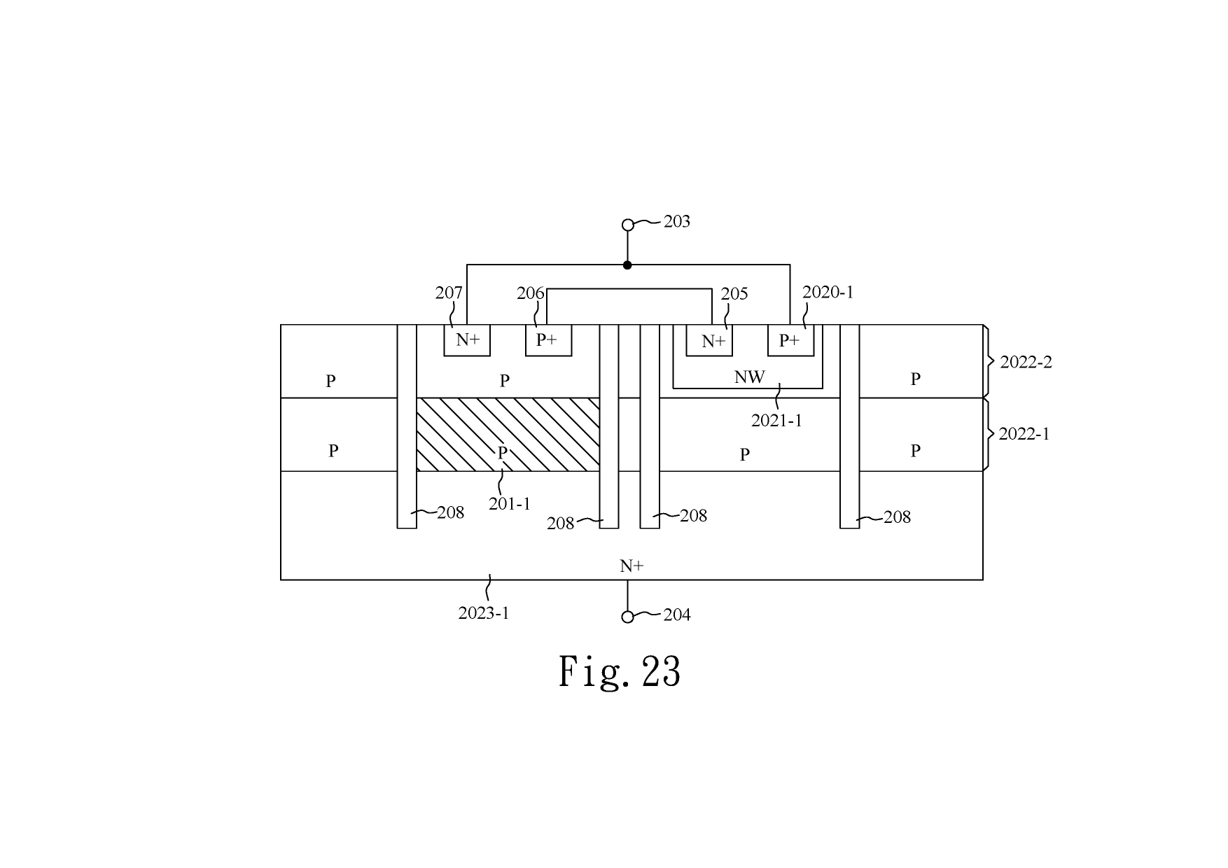

FIG. 23 is a cross-sectional view of an electrostatic discharge protection device according to a fifteenth embodiment of the present invention. Referring to FIG. 23, the fifteenth embodiment is different from the fourth embodiment in the conductivity type. In the fifteenth embodiment, the first conductivity type is a P type and the second conductivity type is an N type. The other structures of the embodiment of FIG. 23 have been described previously so it will not be reiterated.

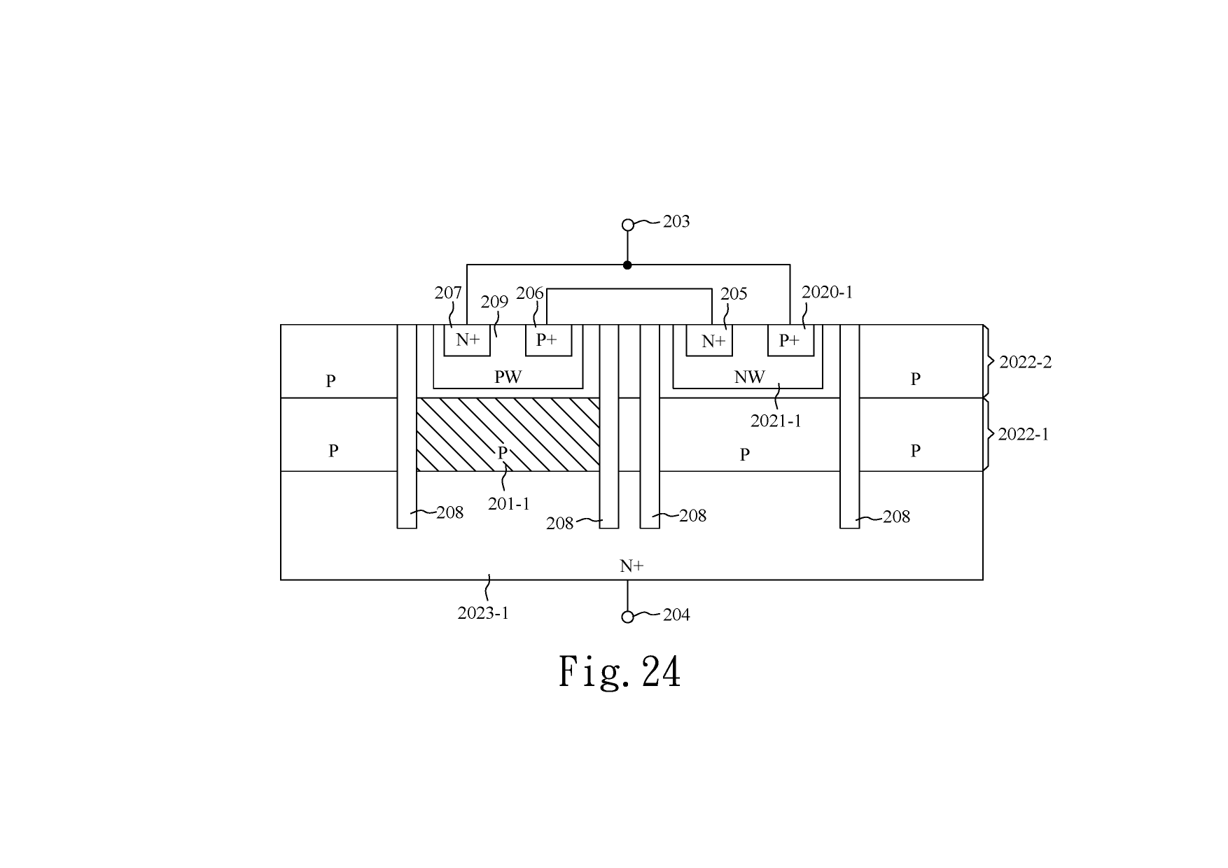

FIG. 24 is a cross-sectional view of an electrostatic discharge protection device according to a sixteenth embodiment of the present invention. Referring to FIG. 24, the sixteenth embodiment is different from the seventh embodiment in the conductivity type. In the sixteenth embodiment, the first conductivity type is a P type and the second conductivity type is an N type. The other structures of the embodiment of FIG. 24 have been described previously so it will not be reiterated.

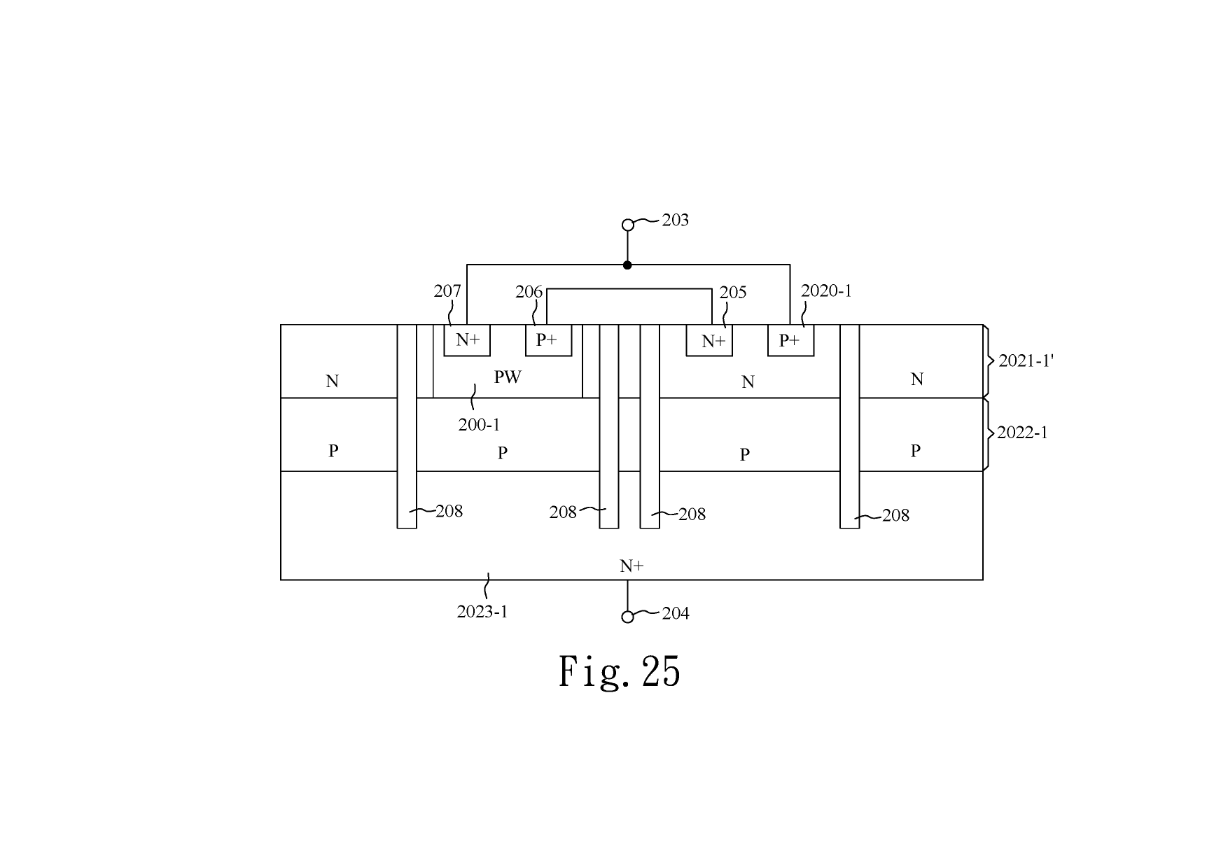

FIG. 25 is a cross-sectional view of an electrostatic discharge protection device according to a seventeenth embodiment of the present invention. Referring to FIG. 25, the seventeenth embodiment is different from the eighth embodiment in the conductivity type. In the seventeenth embodiment, the first conductivity type is a P type and the second conductivity type is an N type. The other structures of the embodiment of FIG. 25 have been described previously so it will not be reiterated.

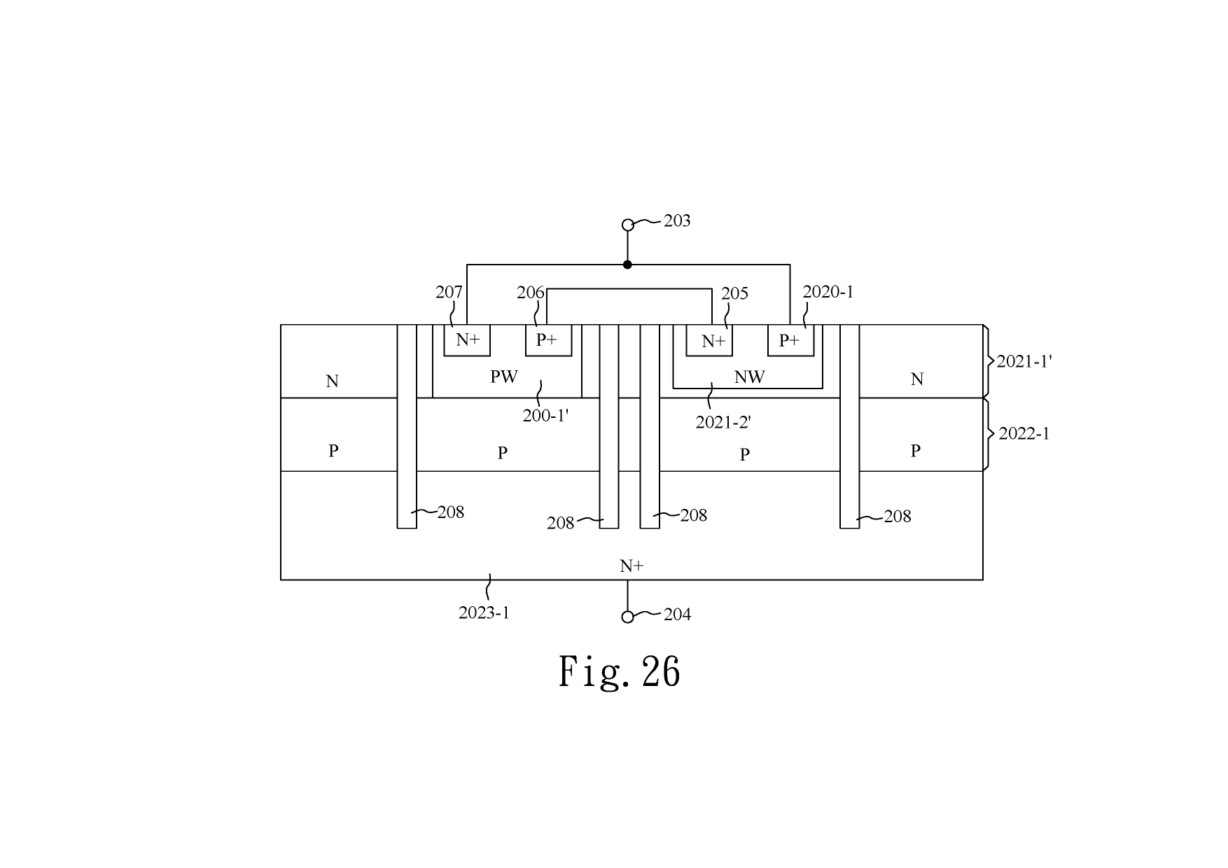

FIG. 26 is a cross-sectional view of an electrostatic discharge protection device according to an eighteenth embodiment of the present invention. Referring to FIG. 26, the eighteenth embodiment is different from the ninth embodiment in the conductivity type. In the eighteenth embodiment, the first conductivity type is a P type and the second conductivity type is an N type. The other structures of the embodiment of FIG. 26 have been described previously so it will not be reiterated.

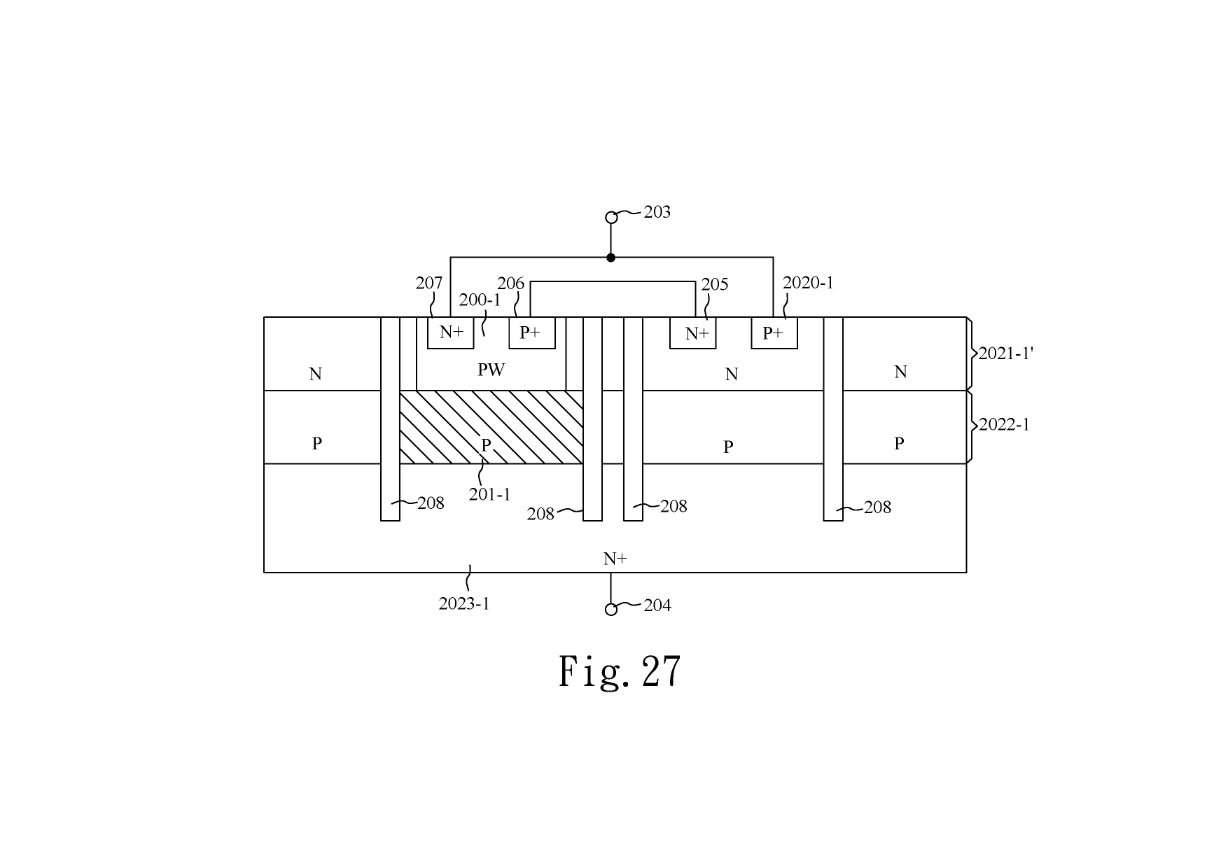

FIG. 27 is a cross-sectional view of an electrostatic discharge protection device according to a nineteenth embodiment of the present invention. Referring to FIG. 27, the nineteenth embodiment is different from the tenth embodiment in the conductivity type. In the nineteenth embodiment, the first conductivity type is a P type and the second conductivity type is an N type. The other structures of the embodiment of FIG. 27 have been described previously so it will not be reiterated.

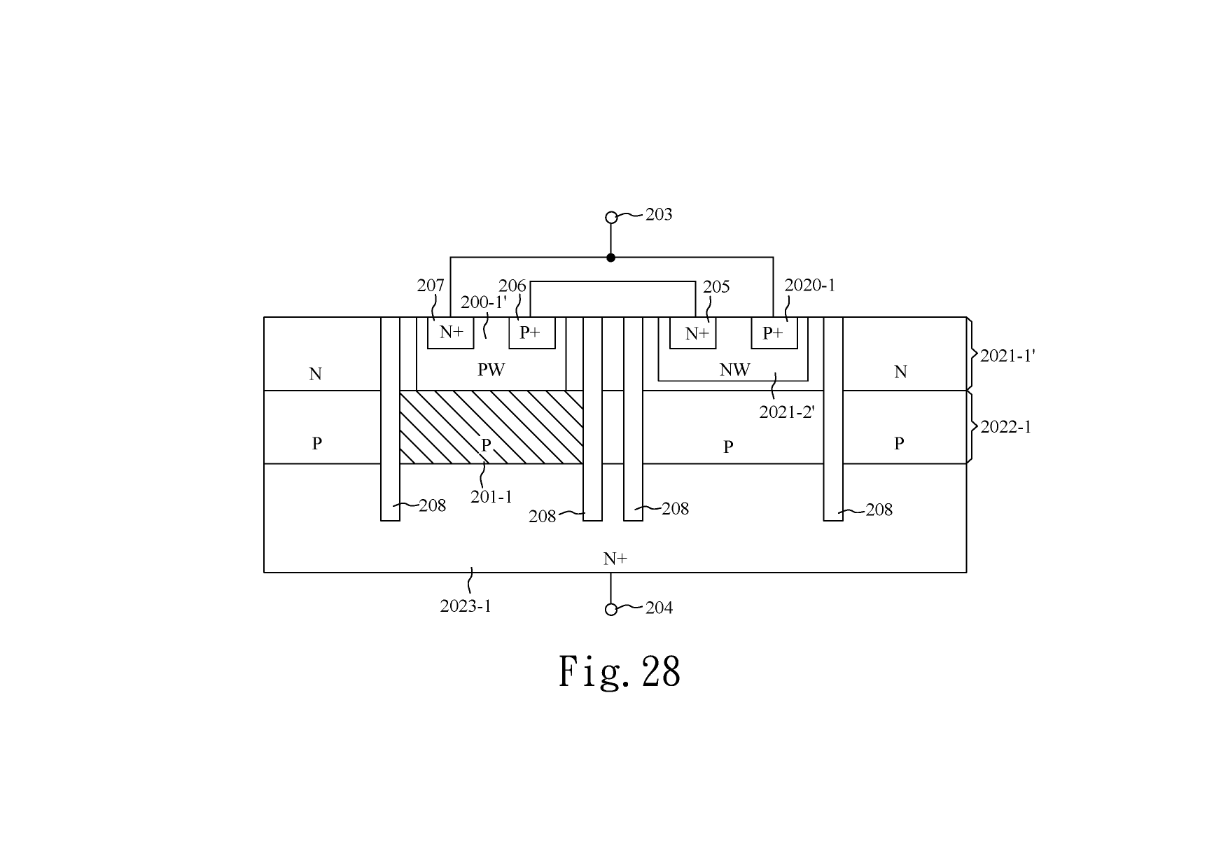

FIG. 28 is a cross-sectional view of an electrostatic discharge protection device according to a twentieth embodiment of the present invention. Referring to FIG. 28, the twentieth embodiment is different from the eleventh embodiment in the conductivity type. In the twentieth embodiment, the first conductivity type is a P type and the second conductivity type is an N type. The other structures of the embodiment of FIG. 28 have been described previously so it will not be reiterated.

According to the embodiments provided above, the electrostatic discharge protection device employs the electronic component as a multi-junction component with low capacitance and uses the voltage clamping component to help trigger on the electronic component, such that the electrostatic discharge protection device has low trigger voltage.

The embodiments described above are only to exemplify the present invention but not to limit the scope of the present invention. Therefore, any equivalent modification or variation according to the shapes, structures, features, or spirit disclosed by the present invention is to be also included within the scope of the present invention.

What is claimed is:

1. An electrostatic discharge protection device comprising:
at least one voltage clamping device comprising:
a diode comprising a first doped area of a first conductivity type and a second doped area of a second conductivity type opposite to the first conductivity type;
a voltage clamping component having a first terminal and a second terminal, wherein the first terminal of the voltage clamping component is electrically connected to the first doped area;
an electronic component comprising a first region of the first conductivity type, a second region of the second conductivity type, a third region of the first conductivity type, and a fourth region of the second conductivity type, wherein the first region, the second region, the third region, and the fourth region are adjacent to each other, the second region is arranged between the first region and the third region, the third region is arranged between the second region and the fourth region, the first region is electrically connected to the second doped area, the second region is electrically connected to the first doped area and the first terminal of the voltage clamping component, the fourth region is electrically connected to the second terminal of the voltage clamping component;
a first pin electrically connected to the second doped area and the first region; and
a second pin electrically connected to the second terminal of the voltage clamping component and the fourth region.

2. The electrostatic discharge protection device according to claim 1, wherein the first conductivity type is an N type and the second conductivity type is a P type.

3. The electrostatic discharge protection device according to claim 2, wherein when the first pin receives a positive pulse voltage and the second pin receives a reference voltage lower than the positive pulse voltage, an electrostatic discharge current flows from the first pin to the second pin through the diode and the voltage clamping component, and when the first pin receives a negative pulse voltage and the second pin receives a reference voltage higher than the negative pulse voltage, a first electrostatic discharge current flows from the second pin to the first pin through the voltage clamping component, the second region, and the first region and a second electrostatic discharge current flows from the second pin to the first pin through the electronic component.

4. The electrostatic discharge protection device according to claim 1, wherein the first conductivity type is a P type and the second conductivity type is an N type.

5. The electrostatic discharge protection device according to claim 4, wherein when the second pin receives a reference voltage and the first pin receives a negative pulse voltage lower than the reference voltage, an electrostatic discharge current flows from the second pin to the first pin through the voltage clamping component and the diode, and when the first pin receives a positive pulse voltage and the second pin receives a reference voltage lower than the positive pulse voltage, a first electrostatic discharge current flows from the first pin to the second pin through the first region, the second region, and the voltage clamping component and a second electrostatic discharge current flows from the first pin to the second pin through the electronic component.

6. The electrostatic discharge protection device according to claim 1, wherein the voltage clamping component is a Zener diode, an NPN bipolar junction transistor whose base is electrically floating, an NPN bipolar junction transistor whose emitter is coupled to its base, a PNP bipolar junction transistor whose base is electrically floating, or a PNP bipolar junction transistor whose emitter is coupled to its base.

7. The electrostatic discharge protection device according to claim 1, wherein the at least one voltage clamping device comprises two voltage clamping devices, and the second pin of one of the two voltage clamping devices is electrically connected to the second pin of another of the two voltage clamping devices.

8. The electrostatic discharge protection device according to claim 1, wherein the at least one voltage clamping device comprises two voltage clamping devices, and the first pin of one of the two voltage clamping devices is electrically connected to the first pin of another of the two voltage clamping devices.

9. The electrostatic discharge protection device according to claim 1, wherein the fourth region is implemented with a heavily-doped region, the third region is implemented with a first epitaxial region and a second epitaxial region, the second region is implemented with a first doped well, the first region is implemented with a first heavily-doped area, the first epitaxial region and the second epitaxial region are sequentially formed on the heavily-doped region, the first doped well is formed in the second epitaxial region, the first heavily-doped area and a second heavily-doped area of the second conductivity type are formed in the first doped well, a third heavily-doped area of the first conductivity type and a fourth heavily-doped area of the second conductivity type are formed in the second epitaxial region, the second heavily-doped area is electrically connected to the third heavily-doped area, the first heavily-doped area is electrically connected to the fourth heavily-doped area, the first doped area is implemented with the second epitaxial region and the third heavily-doped area, the second doped area is implemented with the fourth heavily-doped area, the voltage clamping component is implemented with the heavily-doped region and the first epitaxial region.

10. The electrostatic discharge protection device according to claim 9, wherein a doping concentration of the first epitaxial region is greater than or equal to that of the second epitaxial region.

11. The electrostatic discharge protection device according to claim 9, further comprising two isolation structures formed in the heavily-doped region, the first epitaxial region, and the second epitaxial region, one of the isolation structures surrounds the first doped well, the first heavily-doped area, and the second heavily-doped area, and another of the isolation structures surrounds the third heavily-doped area and the fourth heavily-doped area.

12. The electrostatic discharge protection device according to claim 9, further comprising a buried region of the first conductivity type formed in the first epitaxial region and formed between the fourth heavily-doped area and the heavily-doped region, wherein a doping concentration of the buried region is greater than that of the first epitaxial region.

13. The electrostatic discharge protection device according to claim 1, wherein the fourth region is implemented with a heavily-doped region, the third region is implemented with a first epitaxial region and a second epitaxial region, the second region is implemented with a first doped well, the first region is implemented with a first heavily-doped area, the first epitaxial region and the second epitaxial region are sequentially formed on the heavily-doped region, the first doped well and a second doped well of the first conductivity type are formed in the second epitaxial region, the first heavily-doped area and a second heavily-doped area of the second conductivity type are formed in the first doped well, a third heavily-doped area of the first conductivity type and a fourth heavily-doped area of the second conductivity type are formed in the second doped well, the second heavily-doped area is electrically connected to the third heavily-doped area, the first heavily-doped area is electrically connected to the fourth heavily-doped area, the first doped area is implemented with the second doped well and the third heavily-doped area, the second doped area is implemented with the fourth heavily-doped area, the voltage clamping component is implemented with the heavily-doped region and the first epitaxial region.

14. The electrostatic discharge protection device according to claim 1, wherein the fourth region is implemented with a heavily-doped region, the third region is implemented with a first epitaxial region, the second region is implemented with a second epitaxial region, the first region is implemented with a first heavily-doped area, the first epitaxial region and the second epitaxial region are sequentially formed on the heavily-doped region, the first heavily-doped area and a second heavily-doped area of the second conductivity type are formed in the second epitaxial region, a third heavily-doped area of the first conductivity type and a fourth heavily-doped area of the second conductivity type are formed in a doped well of the first conductivity type, the doped well is formed in the second epitaxial region, the second heavily-doped area is electrically connected to the third heavily-doped area, the first heavily-doped area is electrically connected to the fourth heavily-doped area, the first doped area is implemented with the doped well and the third heavily-doped area, the second doped area is implemented with the fourth heavily-doped area, the voltage clamping component is implemented with the heavily-doped region and the first epitaxial region.
